(19) United States
(12) Patent Application Publication
(10) Pub. No.: US 2022/0165954 A1
(43) Pub. Date: May 26, 2022

(54) FORMULATION CONTAINING A CROSSLINKABLE POLYMER

(71) Applicant: Merck Patent GmbH, Darmstadt (DE)

(72) Inventors: Gaëlle BÉALLE, Heidelberg (DE); Christoph LEONHARD, Otzberg (DE); Hsin-Rong TSENG, Wiesbaden (DE); Manuel HAMBURGER, Mannheim (DE); Pauline HIBON, Weiterstadt (DE)

(21) Appl. No.: 17/603,720

(22) PCT Filed: Apr. 14, 2020
(86) PCT No.: PCT/EP2020/060366

§ 371 Date: Oct. 14, 2021

(30) Foreign Application Priority Data
Apr. 16, 2019 (EP) 19169403.3
Sep. 19, 2021 (EP) 19198305.5

(51) Int. Cl. H01L 51/00; C08L 65/00; C08G 61/12; C09D 165/00

(52) U.S. Cl. CPC H01L 51/0039; C08L 65/00; C08G 61/12; C09D 165/00; C08G 2261/124; C08G 2261/1412; H01L 51/0005; C08G 2261/3162; C08G 2261/411; C08G 2261/512; C08G 2261/95; C08G 2261/92; C08G 2261/91; C08G 2261/3142

(57) ABSTRACT

The present invention relates to a formulation comprising at least one crosslinkable polymer and at least one organic solvent, wherein the at least one crosslinkable polymer is contained in the formulation in a concentration of at least 0.5 g/L, wherein the at least one organic solvent has a boiling point of at least 200° C., characterized in that the solubility of the at least one crosslinkable polymer in the at least one organic solvent is such that the crosslinkable polymer at a concentration of 30 g/L starts to precipitate if 60 vol.-% or less of ethanol is added to the formulation, to the use of these formulations for the preparation of electronic or optoelectronic devices, to a process for the preparation of electronic or optoelectronic devices using these formulations as well as to electronic or optoelectronic devices.

The present invention relates to a formulation comprising at least one crosslinkable polymer and at least one organic solvent, wherein the at least one crosslinkable polymer is contained in the formulation in a concentration of at least 0.5 g/L, wherein the at least one organic solvent has a boiling point of at least 200° C., characterized in that the solubility of the at least one crosslinkable polymer in the at least one organic solvent is such that the crosslinkable polymer at a concentration of 30 g/L starts to precipitate if 60 vol.-% or less of ethanol is added to the formulation.

Moreover, the present invention also relates to the use of the formulations according to the present invention for the preparation of electronic or optoelectronic devices, in particular of organic electroluminescent devices, so-called OLEDs (OLEDs).

Furthermore, the present invention relates to a process for the preparation of an electronic or optoelectronic device, preferably an organic electroluminescent device, having a layer containing a crosslinked polymer with a high degree of crosslinking, characterized in that
a) a formulation of the present invention is applied to a substrate or another layer via a deposition method,
b) the applied formulation is dried in that the at least one solvent is evaporated, and
c) the crosslinkable polymer is crosslinked.

Organic Light Emitting Diodes (OLED) are composed of a multilayer stack deposited between two electrodes. Clear interfaces and low intermixing between the different layers are important to keep good electrical properties and device performance.

Crosslinkable materials are of much interest in soluble processing of multilayers. Indeed, by the application of heat or UV light, crosslinkable material can be converted into an insoluble film. The degree of crosslinking is of concern to enhance solvent resistance of the next soluble layer. Soluble OLED can be inkjet-printed and allows to achieve high resolution panels which are of importance for OLED screens (TVs, smartphones, smartwatches, etc.).

The challenge is to find a suitable solvent, solubilizing the crosslinkable material and having a suitable viscosity, surface tension and boiling point to be deposited by inkjet printing while the solvent does not degrade the crosslinking reaction. Due to their high boiling point, solvent residuals are found in thin films. Their interaction with the material need to be known to have the optimal material properties in the film.

Starting from the known state of the art, it can be regarded as an object of the present invention to provide formulations containing crosslinkable polymers. The crosslinkable polymers must have the desired electro-optical properties and have sufficient solubility in the solvent or solvent mixture used. The solvents must be selected with their properties such that they dissolve the crosslinkable polymer in sufficient quantity, and that they have corresponding physical properties, such as viscosity and boiling point, so that the formulations obtained by printing and coating techniques, such as. Ink jet printing, let process.

This object is achieved according to the present invention by the provision of formulations containing at least one crosslinkable polymer and at least one organic solvent, characterized in that the at least organic solvent is chosen in such a manner that the solubility of the at least one crosslinkable polymer in the at least one organic solvent is such that the at least one crosslinkable polymer starts to precipitate if 60 vol.-% or less of ethanol is added to the formulation.

Object of the present invention are formulations comprising at least one crosslinkable polymer and at least one organic solvent, wherein the at least one crosslinkable polymer is contained in the formulation in a concentration of at least 0.5 g/L, wherein the at least one organic solvent has a boiling point of at least 200° C., characterized in that the solubility of the at least one crosslinkable polymer in the at least one organic solvent is such that the at least one crosslinkable polymer at a concentration of 30 g/L starts to precipitate if 60 vol.-% or less of ethanol is added to the formulation.

The expression “at least one organic solvent” as used in the present application means one or more, preferably one, two, three, four or five, more preferably one, two or three, organic solvents.

In a first preferred embodiment, the formulation according to the present invention contains one organic solvent, in the following also mentioned as the first organic solvent or the organic solvent of the present invention. More preferably, the formulation according to the present invention consists of one organic solvent.

The expression “at least one crosslinkable polymer” as used in the present application means one or more, preferably one or two, more preferably one crosslinkable polymer.

In a second preferred embodiment, the formulation according to the present invention contains one crosslinkable polymer. More preferably, the formulation according to the present invention consists of one crosslinkable polymer.

In a third preferred embodiment, the formulation according to the present invention consists of one crosslinkable polymer and one organic solvent.

In a fourth preferred embodiment, the crosslinkable polymer starts to precipitate if 45 vol.-% of less, more preferably 35 vol.-% or less, most preferably 25 vol.-% or less and especially most preferably 22 vol.-% or less of ethanol is added to the formulation.

The ethanol, which is added to the formulation of the present invention should have a purity of ≥99.5%, determined via gaschromatography (GC).

The formulation according to the present invention has a viscosity of ≤25 mPas. Preferably, the formulation has a viscosity in the range from 1 to 20 mPas, and more preferably in the range from 1 to 15 mPas.

The viscosity of the formulations of the present invention and the solvent is measured with a 1° cone-disc rotation discometer type Discovery AR3 (Thermo Scientific). The equipment allows precise control of temperature and shear rate. The measurement of the viscosity is carried out at a temperature of 25.0° C. (+/−0.2° C.) and a shear rate of 500 s⁻¹. Each sample is measured three times and the results obtained are averaged.

The formulation according to the present invention preferably has a surface tension in the range from 15 to 70 mN/m, more preferably in the range from 20 to 50 mN/m and most preferably in the range from 25 to 40 mN/m.

The organic solvent preferably has a surface tension in the range from 15 to 70 mN/m, more preferably in the range from 20 to 50 mN/m and most preferably in the range from 25 to 40 mN/m.

The surface tension can be measured using a FTA (First Ten Angstrom) 1000 contact angle goniometer at 20° C. Details of the method are from First Ten Angstrom, as by Roger P. Woodward, Ph.D. “Surface tension measurements using the drop-shape method”, available. Preferably, the pendant drop method can be used to determine the surface tension. This measuring technique uses a hanging drop from a needle into a liquid or gaseous phase. The shape of the drop results from the relationship between surface tension, gravity and density differences. Using the pendant drop method, the surface tension is calculated from the silhouette of a hanging drop at http://www.kruss.de/services/education-theory/glossary/drop-shape-analysis. A commonly used and commercially available precision drop contour analysis tool, FTA 1000 from First Ten Angstrom, was used to perform all surface tension measurements. The surface tension is determined by the software FTA 1000. All measurements were carried out at room temperature in the range between 20° C. and 25° C. The standard procedure involves determining the surface tension of each formulation using a fresh one-way drop dispensing system (syringe and needle). Each drop is measured over the course of one minute with 60 measurements, which are averaged later. For each formulation, three drops are measured. The final value is averaged over these measurements. The tool is regularly tested against various liquids with known surface tensions.

In addition, the at least one organic solvent preferably has boiling point at atmospheric pressure of at least 200° C., more preferably a boiling point of at least 220° C. and most preferably a boiling point of at least 240° C.

Organic solvents, which can preferably be used as the first organic solvent are shown in the following table.

| | | |
|---|---|---|
| 1- Methylnaphthalene (1-MN) | 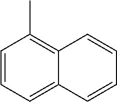 | CAS 90- 12-0 |
| 1- Methoxynaphthalene (1-MENA) | 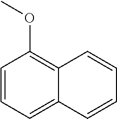 | CAS 2216- 69-5 |
| 3-Phenoxytoluene (3-PT) | 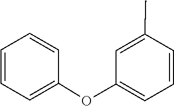 | CAS 3586- 14-9 |
| Cyclohexylhexanoate (CHH) | 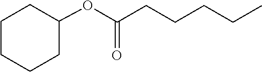 | CAS 6243- 10-3 |
| Menthyl isovalerate (Menthoval) | 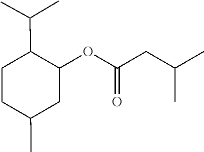 [SMILES: CC(C)CC(=O)OC1CC(C)CCC1C(C)C] | CAS 16409- 46-4 |

If the formulation according to the present invention contains more than one organic solvent, it contains beside the first organic solvent at least a further organic solvent, in the following also mentioned as the second organic solvent.

Suitable and preferred second organic solvents are, for example, toluene, anisole, o-, m- or p-xylene, methyl benzoate, mesitylene, tetralin, veratrol, THF, methyl-THF, THP, chlorobenzene, dioxane, (−)-fenchone, 1,2,3,5-tetramethylbenzene, 1,2,4,5-tetramethylbenzene, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclohexanol, cyclohexanone, cyclohexylbenzene, decalin, dodecylbenzene, ethyl benzoate, indane, methyl benzoate, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)-ethane or mixtures of these solvents.

Surprisingly, it has been found that the formulation of the present invention containing an organic solvent of the present invention, when used for the preparation of an electronic or optoelectronic device, in particular of an organic electroluminescent device, leeds to a higher degree of crosslinking of the crosslinkable polymer compared with the prior art using one or more solvents, wherein the solubility of the at least one crosslinkable polymer in these one or more organic solvents is such that the at least one crosslinkable polymer starts to precipitate if more than 60 vol.-% of ethanol is added to the formulation.

Furthermore, it has been found surprisingly that the formulation of the present invention containing an organic solvent of the present invention, when used for the preparation of an electronic or optoelectronic device, in particular of an organic electroluminescent device, leeds to a higher efficiency of the organic electroluminescent device compared with devices prepared according to the prior art using one or more solvents, wherein the solubility of the at least one crosslinkable polymer in these one or more organic solvents is such that the at least one crosslinkable polymer starts to precipitate if more than 60 vol.-% of ethanol is added to the formulation. Consequently, the present invention also relates to a process for the preparation of an electronic or optoelectronic device, preferably an organic electroluminescent device, having a layer containing a crosslinked polymer with a high degree of crosslinking, characterized in that
d) a formulation of the present invention is applied to a substrate or another layer via a deposition method,
e) the applied formulation is dried in that the at least one solvent is evaporated, and
f) the crosslinkable polymer is crosslinked.

The present invention furthermore relates to a process for the preparation of an electronic or optoelectronic device, preferably an organic electroluminescent device, having a layer containing at least one crosslinked polymer with a specific degree of crosslinking, wherein this degree is obtained in that a formulation according to the present invention is used, characterized in that this degree can be increased in that at least one organic solvent having a boiling point of at least 200° C. is used in which the solubility of the at least one crosslinkable polymer is such that the at least one crosslinkable polymer at a concentration of 30 g/L starts to precipitate if a lower amount of ethanol is added to the formulation, and characterized in that this degree can be decreased in that at least one organic solvent having a boiling point of at least 200° C. is used in which the solubility of the at least one crosslinkable polymer is such that the at least one crosslinkable polymer at a concentration of 30 g/L starts to precipitate if a higher amount of ethanol is added to the formulation.

A high degree of crosslinking according to the present invention means either,
that the degree of crosslinking in a film formed from a formulation of the present invention is preferably >15%, more preferably >50%, as measured in accordance with the experimental part G of the present application, or
that the damage of a formed film is preferably less than 70%, more preferably less than 30% as measured in accordance with the experimental part F of the present application.

As deposition method, any kind of deposition method known to a person skilled in the art can be used.

Suitable and preferred deposition methods include liquid coating and printing techniques. Preferred deposition methods include, without limitation, dip coating, spin coating, spray coating, aerosol jetting, ink jet printing, nozzle printing, gravure printing, doctor blade coating, roller printing, reverse-roller printing, flexographic printing, web printing, screen printing, stencil printing, spray coating, dip coating, curtain coating, kiss coating, meyer bar coating, 2 roll nip fed coating, anilox coaters, knife coating or slot dye coating. The most preferred deposition method is ink jet printing.

The formulation can be evaporated with any kind of evaporation method known to a person skilled in the art. Preferably, the formulation is evaporated using elevated temperature and/or reduced pressure.

The crosslinking of the crosslinkable polymer can be conducted using any crosslinking method known to a person skilled in the art. Preferably, the crosslinking is conducted using elevated temperature and/or reduced pressure, preferably using elevated temperature.

The crosslinkable polymer preferably has a solubility of ≥0.5 g/L in the at least one organic solvent, more preferably a solubility of ≥3 g/L and most preferably ≥10 g/L.

The concentration of the crosslinkable polymer in the formulation is preferably in the range of 0.5 to 50 g/L, more preferably in the range of 1 to 30 g/L.

The crosslinkable polymer according to the present invention is a polymer comprising at least one, preferably one, repeating unit which contains at least one, preferably one, crosslinkable group. The repeating unit, which contains at least one crosslinkable group is also named as crosslinkable repeating unit.

In the present application, the term polymer is taken to mean both polymeric compounds as well as oligomeric compounds and dendrimers. The polymeric compounds according to the present invention preferably contain 10 to 10000, more preferably 10 to 5000 and most preferably 10 to 2000 structural units (i.e. recurring units). The oligomeric compounds according to the present invention preferably contain 3 to 9 structural units. The branching factor of the polymers here is between 0 (linear polymer, no branching points) and 1 (fully branched dendrimer).

The at least one crosslinkable polymer according to the present invention preferably has a molecular weight M_{w} in the range from 1,000 to 2,000,000 g/mol, more preferably a molecular weight M_{w} in the range from 10,000 to 1,500,000 g/mol and most preferably a molecular weight M_{w} in the range from 50,000 to 1,000,000 g/mol. The molecular weight M_{w} is determined by means of GPC(=gel permeation chromatography) against an internal polystyrene standard.

The crosslinkable polymers according to the present invention are either conjugated, partially conjugated or non-conjugated polymers. Preference is given to conjugated or partially conjugated polymers.

The crosslinkable repeating unit can in accordance with the invention be incorporated into the main chain or into the side chain of the polymer. However, the crosslinkable repeating unit is preferably incorporated into the main chain of the polymer. In the case of incorporation into the side chain of the polymer, the crosslinkable repeating unit can be either monovalent or divalent, i.e. they have either one ot two bonds to adjacent structural units in the polymer.

“Conjugated polymers” in the sense of the present application are polymers which contain principally sp²-hybridised (or optionally also sp-hybridised) carbon atoms in the main chain, which may also be replaced by correspondingly hybridised heteroatoms. In the simplest case, this means the alternating presence of double and single bonds in the main chain, but polymers containing units such as, for example, a meta-linked phenylene are also intended to be regarded as conjugated polymers in the sense of this application. “Principally” means that naturally (spontaneously) occurring defects which result in conjugation interruptions do not devalue the term “conjugated polymer”. The term conjugated polymers is likewise applied to polymers having a conjugated main chain and non-conjugated side chains. Furthermore, the term conjugated is likewise used in the present application if the main chain contains, for example, arylamine units, arylphosphine units, certain heterocycles (i.e. conjugation via N, O or S atoms) and/or organometallic complexes (i.e. conjugation via the metal atom). An analogous situation applies to conjugated dendrimers. By contrast, units such as, for example, simple alkyl bridges, (thio)ether, ester, amide or imide links are clearly defined as non-conjugated segments.

A partially conjugated polymer in the present application is intended to be taken to mean a polymer which contains conjugated regions which are separated from one another by non-conjugated sections, specific conjugation interrupters (for example spacer groups) or branches, for example in which relatively long conjugated sections in the main chain are interrupted by non-conjugated sections, or which contains relatively long conjugated sections in the side chains of a polymer which is non-conjugated in the main chain. Conjugated and partially conjugated polymers may also contain conjugated, partially conjugated or non-conjugated dendrimers.

The term “dendrimer” in the present application is intended to be taken to mean a highly branched compound built up from a multifunctional centre (core), to which branched monomers are bonded in a regular structure, so that a tree-like structure is obtained. Both the core and also the monomers here can adopt any desired branched structures which consist both of purely organic units and also organometallic compounds or coordination compounds. “Dendrimer” here is generally intended to be understood as described, for example, by M. Fischer and F. Vögtle (Angew. Chem., Int. Ed. 1999, 38, 885).

The term “repeating unit” in the present application is taken to mean a unit which, starting from a monomer unit which contains at least two, preferably two, reactive groups, is incorporated into the polymer backbone as a part thereof by reaction with bond formation and is thus present in the polymer prepared as linked recurring unit.

The crosslinkable polymer of the formulation of the present invention contains at least one crosslinkable repeating unit. The proportion of the at least one crosslinkable repeating unit in the crosslinkable polymer is in the range from 0.01 to 50 mol %, preferably in the range from 0.1 to 30 mol %, more preferably in the range from 0.5 to 25 mol % and most preferably in the range from 1 to 20 mol %, based on 100 mol % of all repeating units in the polymer.

“Crosslinkable group Q” in the sense of the present invention denotes a functional group which is capable of undergoing a reaction and thus forming an insoluble compound. The reaction here can take place with a further, identical group Q, a further, different group Q or any desired other part thereof or another polymer chain. The crosslinkable group is thus a reactive group. A correspondingly crosslinked compound is obtained here as a result of the reaction of the crosslinkable group. The chemical reaction can also be carried out in the layer, where an insoluble layer forms. The crosslinking can usually be supported by heat or by UV, microwave, X-ray or electron radiation, optionally in the presence of an initiator. “Insoluble” in the sense of the present invention preferably means that the polymer according to the invention after the crosslinking reaction, i.e. after the reaction of the crosslinkable groups, has a solubility at room temperature in an organic solvent which is at least a factor of 3, preferably at least a factor of 10, lower than that of the corresponding uncrosslinked polymer according to the invention in the same organic solvent.

The repeating unit which carries the crosslinkable group Q can be selected from all repeating units known to a person skilled in the art.

In a preferred embodiment, the repeating unit which carries the crosslinkable group Q is a unit of the following formula (I):

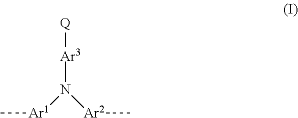

where
Ar¹ to Ar³ is on each occurrence, in each case identically or differently, a mono- or polycyclic, aromatic or heteroaromatic ring system having 5 to 60 aromatic ring atoms, which may be substituted by one or more radicals R;
R is on each occurrence, identically or differently, H, D, F, Cl, Br, I, N(R¹)₂, CN, NO₂, Si(R¹)₃, B(OR¹)₂, C(═O)R¹, P(═O)(R¹)₂, S(═O)R¹, S(═O)₂R¹, OSO₂R¹, a straight-chain alkyl, alkoxy or thioalkoxy group having 1 to 40 C atoms or a branched or cyclic alkyl, alkoxy or thioalkoxy group having 3 to 40 C atoms, each of which may be substituted by one or more radicals R¹, where one or more non-adjacent CH₂ groups may be replaced by R¹C═CR¹, C≡C, Si(R¹)₂, C═O, C═S, C═NR¹, P(═O)(R¹), SO, SO₂, NR¹, O, S or CONR¹ and where one or more H atoms may be replaced by D, F, Cl, Br, I or CN, or a mono- or polycyclic, aromatic or heteroaromatic ring system having 5 to 60 aromatic ring atoms, which may in each case be substituted by one or more radicals R¹, or an aryloxy or heteroaryloxy group having 5 to 60 aromatic ring atoms, which may be substituted by one or more radicals R¹, or an aralkyl or heteroaralkyl group having 5 to 60 aromatic ring atoms, which may be substituted by one or more radicals R¹, or a diarylamino group, diheteroarylamino group or arylheteroarylamino group having 10 to 40 aromatic ring atoms, which may be substituted by one or more radicals R¹, or a crosslinkable group Q, where two or more radicals R may also form a mono- or polycyclic, aliphatic, aromatic and/or benzo-fused ring system with one another;
R¹ is on each occurrence, identically or differently, H, D, F or an aliphatic hydrocarbon radical having 1 to 20 C atoms, an aromatic and/or a heteroaromatic hydrocarbon radical having 5 to 20 C atoms, in which, in addition, one or more H atoms may be replaced by F; where two or more substituents R¹ may also form a mono- or polycyclic, aliphatic or aromatic ring system with one another; and the dashed lines represent bonds to adjacent repeating units in the polymer.

The term “mono- or polycyclic, aromatic ring system” in the present application is taken to mean an aromatic ring system having 6 to 60, preferably 6 to 30 and particularly preferably 6 to 24 aromatic ring atoms, which does not necessarily contain only aromatic groups, but instead in which a plurality of aromatic units may also be interrupted by a short non-aromatic unit (<10% of the atoms other than H, preferably <5% of the atoms other than H), such as, for example, sp³-hybridised C atom or O or N atom, CO group, etc. Thus, for example, systems such as, for example, 9,9′-spirobifluorene and 9,9-diarylfluorene are also intended to be taken to be aromatic ring systems.

The aromatic ring systems may be mono- or polycyclic, i.e. they may contain one ring (for example phenyl) or a plurality of rings, which may also be condensed (for example naphthyl) or covalently linked (for example biphenyl), or contain a combination of condensed and linked rings.

Preferred aromatic ring systems are, for example, phenyl, biphenyl, terphenyl, [1,1′:3′,1″ ]terphenyl-2′-yl, quaterphenyl, naphthyl, anthracene, binaphthyl, phenanthrene, dihydrophenanthrene, pyrene, dihydropyrene, chrysene, perylene, tetracene, pentacene, benzopyrene, fluorene, indene, indenofluorene and spirobifluorene.

The term “mono- or polycyclic, heteroaromatic ring system” in the present application is taken to mean an aromatic ring system having 5 to 60, preferably 5 to 30 and particularly preferably 5 to 24 aromatic ring atoms, where one or more of these atoms is (are) a heteroatom. The “mono- or polycyclic, heteroaromatic ring system” does not necessarily contain only aromatic groups, but instead may also be interrupted by a short non-aromatic unit (<10% of the atoms other than H, preferably <5% of the atoms other than H), such as, for example, sp³-hybridised C atom or O or N atom, CO group, etc.

The heteroaromatic ring systems may be mono- or polycyclic, i.e. they may contain one ring or a plurality of rings, which may also be condensed or covalently linked (for example pyridylphenyl), or contain a combination of condensed and linked rings. Preference is given to fully conjugated heteroaryl groups.

Preferred heteroaromatic ring systems are, for example, 5-membered rings, such as pyrrole, pyrazole, imidazole, 1,2,3-triazole, 1,2,4-triazole, tetrazole, furan, thiophene, selenophene, oxazole, isoxazole, 1,2-thiazole, 1,3-thiazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 6-membered rings, such as pyridine, pyridazine, pyrimidine, pyrazine, 1,3,5-triazine, 1,2,4-triazine, 1,2,3-triazine, 1,2,4,5-tetrazine, 1,2,3,4-tetrazine, 1,2,3,5-tetrazine, or condensed groups, such as carbazole, indenocarbazole, indole, isoindole, indolizine, indazole, benzimidazole, benzotriazole, purine, naphthimidazole, phenanthrimidazole, pyridimidazole, pyrazinimidazole, quinoxalinimidazole, benzoxazole, naphthoxazole, anthroxazole, phenanthroxazole, isoxazole, benzothiazole, benzofuran, isobenzofuran, dibenzofuran, quinoline, isoquinoline, pteridine, benzo-5,6-quinoline, benzo-6,7-quinoline, benzo-7,8-quinoline, benzoisoquinoline, acridine, phenothiazine, phenoxazine, benzopyridazine, benzopyrimidine, quinoxaline, phenazine, naphthyridine, azacarbazole, benzocarboline, phenanthridine, phenanthroline, thieno[2,3b]thiophene, thieno[3,2b]thiophene, dithienothiophene, isobenzothiophene, dibenzothiophene, benzothiadiazothiophene or combinations of these groups.

The mono- or polycyclic, aromatic or heteroaromatic ring system may be unsubstituted or substituted. Substituted in the present application means that the mono- or polycyclic, aromatic or heteroaromatic ring system contains one or more substituents R.

R is on each occurrence preferably, identically or differently, H, D, F, Cl, Br, I, N(R¹)₂, CN, NO₂, Si(R¹)₃, B(OR¹)₂, C(═O)R¹, P(═O)(R¹)₂, S(═O)R¹, S(═O)₂R¹, OSO₂R¹, a straight-chain alkyl, alkoxy or thioalkoxy group having 1 to 40 C atoms or an alkenyl or alkynyl group having 2 to 40 C atoms or a branched or cyclic alkyl, alkoxy or thioalkoxy group having 3 to 40 C atoms, each of which may be substituted by one or more radicals R¹, where one or more non-adjacent CH₂ groups may be replaced by R¹C═CR¹, C≡C, Si(R¹)₂, C═O, C═S, C═NR¹, P(═O)(R¹), SO, SO₂, NR¹, O, S or CONR¹ and where one or more H atoms may be replaced by D, F, Cl, Br, I or CN, or an aromatic or heteroaromatic ring system having 5 to 60 aromatic ring atoms, which may in each case be substituted by one or more radicals R¹, or an aryloxy or heteroaryloxy group having 5 to 60 aromatic ring atoms, which may be substituted by one or more radicals R¹, or an aralkyl or heteroaralkyl group having 5 to 60 aromatic ring atoms, which may be substituted by one or more radicals R¹, or a diarylamino group, diheteroarylamino group or arylheteroarylamino group having 10 to 40 aromatic ring atoms, which may be substituted by one or more radicals R¹; two or more radicals R here may also form a mono- or polycyclic, aliphatic, aromatic and/or benzo-fused ring system with one another.

R is on each occurrence more preferably, identically or differently, H, F, Cl, Br, I, N(R¹)₂, Si(R¹)₃, B(OR¹)₂, C(═O)R¹, P(═O)(R¹)₂, a straight-chain alkyl or alkoxy group having 1 to 20 C atoms or an alkenyl or alkynyl group having 2 to 20 C atoms or a branched or cyclic alkyl or alkoxy group having 3 to 20 C atoms, each of which may be substituted by one or more radicals R¹, where one or more non-adjacent CH₂ groups may be replaced by R¹C═CR¹, C≡C, Si(R¹)₂, C═O, C═NR¹, P(═O)(R¹), NR¹, O or CONR¹ and where one or more H atoms may be replaced by F, Cl, Br or I, or an aromatic or heteroaromatic ring system having 5 to 30 aromatic ring atoms, which may in each case be substituted by one or more radicals R¹, or an aryloxy or heteroaryloxy group having 5 to 30 aromatic ring atoms, which may be substituted by one or more radicals R¹, or an aralkyl or heteroaralkyl group having 5 to 30 aromatic ring atoms, which may be substituted by one or more radicals R¹, or a diarylamino group, diheteroarylamino group or arylheteroarylamino group having 10 to 20 aromatic ring atoms, which may be substituted by one or more radicals R¹; two or more radicals R here may also form a mono- or polycyclic, aliphatic, aromatic and/or benzo-fused ring system with one another.

R is on each occurrence most preferably, identically or differently, H, a straight-chain alkyl or alkoxy group having 1 to 10 C atoms or an alkenyl or alkynyl group having 2 to 10 C atoms or a branched or cyclic alkyl or alkoxy group having 3 to 10 C atoms, each of which may be substituted by one or more radicals R¹, where one or more non-adjacent CH₂ groups may be replaced by R¹C═CR¹, C≡C, C═O, C═NR¹, NR¹, O or CONR¹, or an aromatic or heteroaromatic ring system having 5 to 20 aromatic ring atoms, which may in each case be substituted by one or more radicals R¹, or an aryloxy or heteroaryloxy group having 5 to 20 aromatic ring atoms, which may be substituted by one or more radicals R¹, or an aralkyl or heteroaralkyl group having 5 to 20 aromatic ring atoms, which may be substituted by one or more radicals R¹, or a diarylamino group, diheteroarylamino group or arylheteroarylamino group having 10 to 20 aromatic ring atoms, which may be substituted by one or more radicals R¹; two or more radicals R here may also form a mono- or polycyclic, aliphatic, aromatic and/or benzo-fused ring system with one another.

R¹ is on each occurrence preferably, identically or differently, H, D, F or an aliphatic, aromatic and/or heteroaromatic hydrocarbon radical having 1 to 20 C atoms, in which, in addition, one or more H atoms may be replaced by F; two or more substituents R¹ here may also form a mono- or polycyclic, aliphatic or aromatic ring system with one another.

R¹ is on each occurrence more preferably, identically or differently, H or an aliphatic, aromatic and/or heteroaromatic hydrocarbon radical having 1 to 20 C atoms; two or more substituents R¹ here may also form a mono- or polycyclic, aliphatic or aromatic ring system with one another.

R¹ is on each occurrence most preferably, identically or differently, H or an aliphatic, aromatic and/or heteroaromatic hydrocarbon radical having 1 to 10 C atoms.

Preferred mono- or polycyclic, aromatic or heteroaromatic groups Ar¹ in formula (I) are the following:

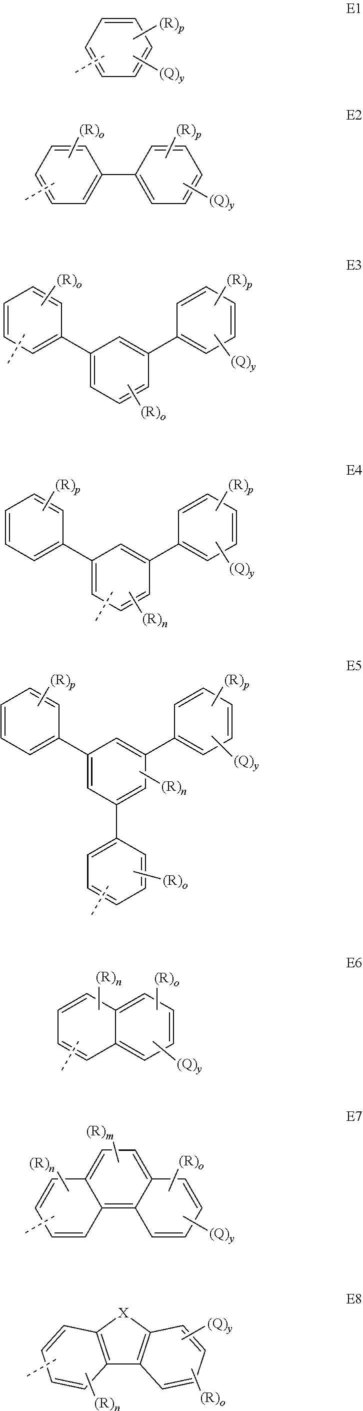

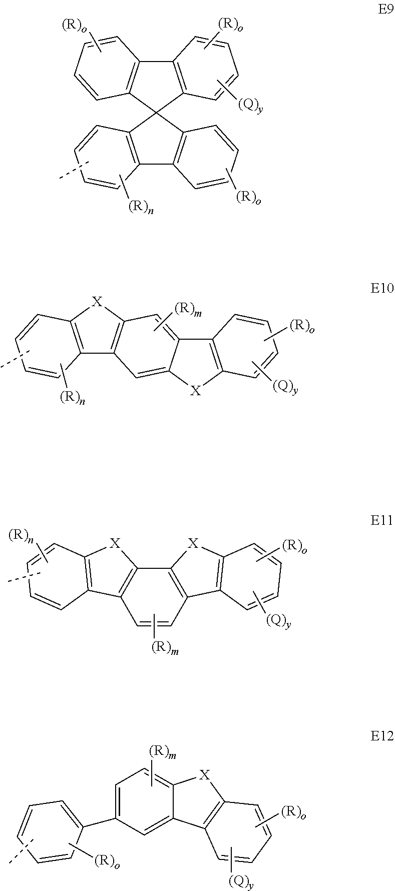

The radicals R in the formulae E1 to E12 can adopt the same meaning as the radicals R in the formula (I). X can denote CR₂, SiR₂, NR, O or S, where here too R can adopt the same meaning as the radicals R in the formula (I); Q is a crosslinkable group;

m=0, 1 or 2;

n=0, 1, 2 or 3;

o=0, 1, 2, 3 or 4 and

p=0, 1, 2, 3, 4 or 5;

but with the proviso that with respect to a phenylene group the sum (p+y) is ≤5 and the sum (o+y) is ≤4 ist, and with the proviso that in each repeating unit y is ≥1.

Preferred mono- or polycyclic, aromatic or heteroaromatic groups Ar² and Ar³ in formula (I) are the following:

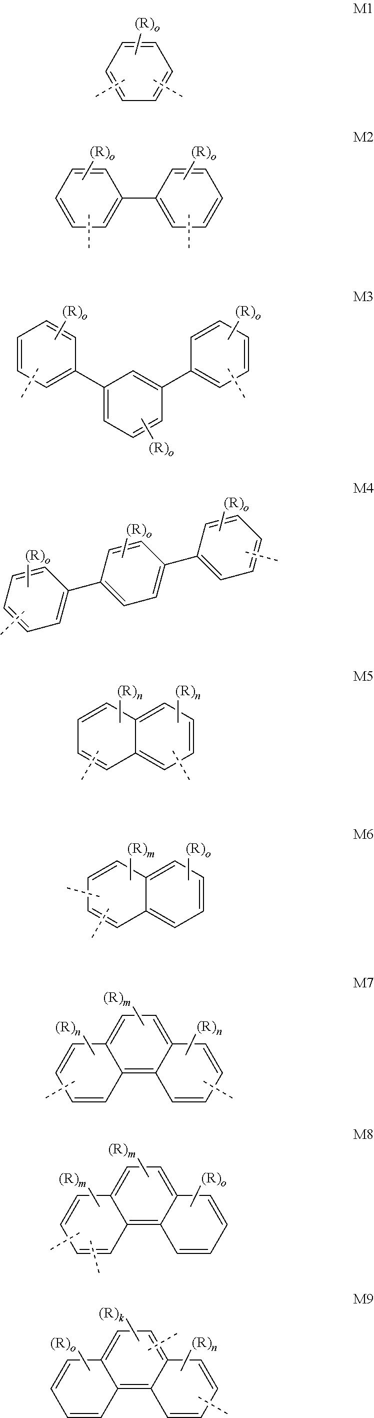

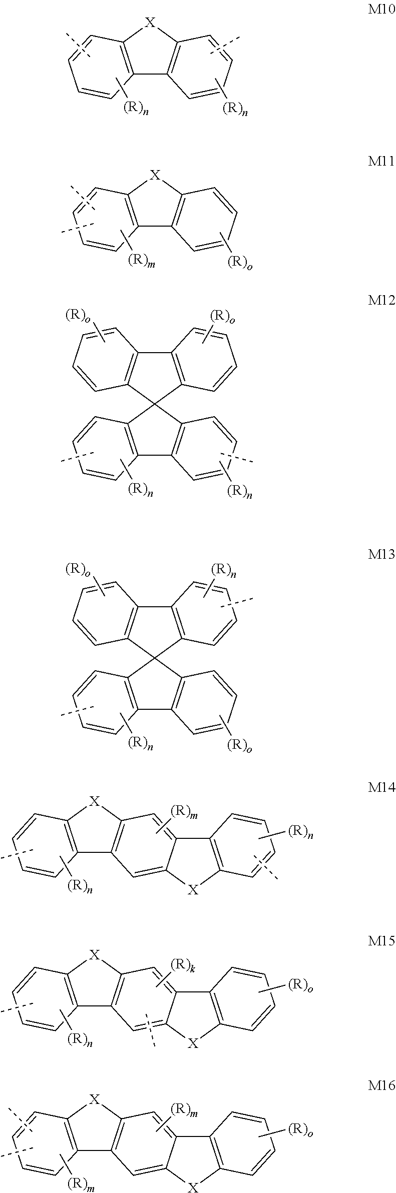

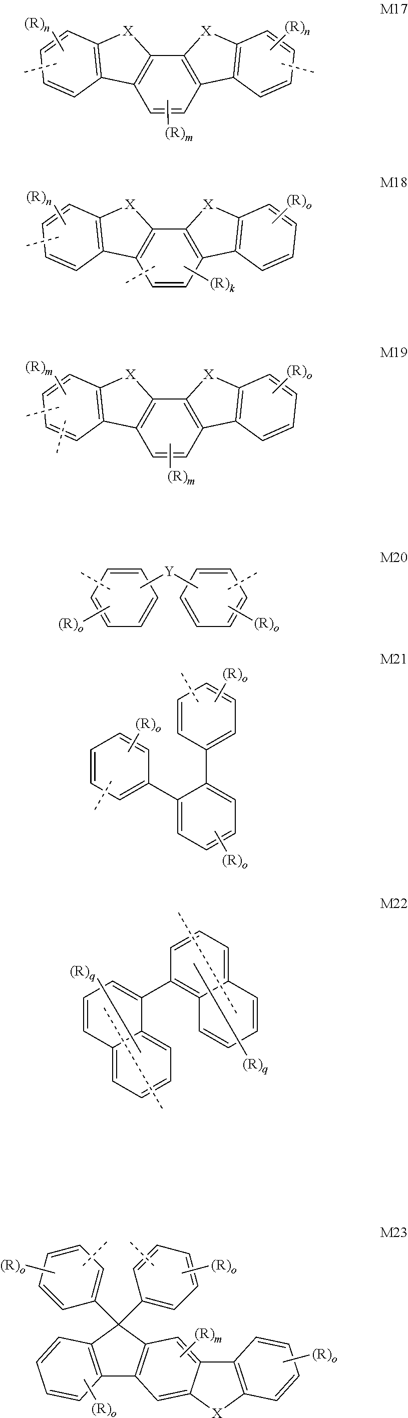

The radicals R in the formulae M1 to M23 can adopt the same meaning as the radicals R in the formula (I). X can denote CR₂, SiR₂, O or S, where here too R can adopt the same meaning as the radicals R in the formula (I). Y can be CR₂, SiR₂, O, S or a straight-chain or branched alkyl group having 1 to 20 C atoms or an alkenyl or alkynyl group having 2 to 20 C atoms, each of which may be substituted by one or more radicals R¹, and where one or more non-adjacent CH₂ groups, CH groups or C atoms of the alkyl, alkenyl or alkynyl groups may be replaced by Si(R¹)₂, C═O, C═S, C═NR¹, P(═O)(R¹), SO, SO₂, NR¹, O, S, CONR¹, or an aromatic or heteroaromatic ring system having 5 to 60 aromatic ring atoms, which may in each case be substituted by one or more radicals R¹, or an aryloxy or heteroaryloxy group having 5 to 60 aromatic ring atoms, which may be substituted by one or more radicals R¹, or an aralkyl or heteroaralkyl group having 5 to 60 aromatic ring atoms, which may be substituted by one or more radicals R¹, or a diarylamino group, diheteroarylamino group or arylheteroarylamino group having 10 to 40 aromatic ring atoms, which may be substituted by one or more radicals R¹; where here too the radicals R and R¹ can adopt the same meanings as the radicals R and R¹ in the formula (I).

The indices used have the following meaning:

k=0 or 1;

m=0, 1 or 2;

n=0, 1, 2 or 3;

o=0, 1, 2, 3 or 4; and

q=0, 1, 2, 3, 4, 5 or 6.

In a further preferred embodiment, the repeating unit which carries the at least one crosslinkable group Q is a unit of the following formula (II):

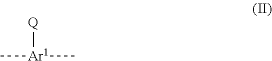

where Ar¹ is a mono- or polycyclic, aromatic or heteroaromatic ring system having 5 to 60 aromatic ring atoms, which may be substituted by one or more radicals R, as defined above with respect to formula (I).

The crosslinkable repeating unit of formula (II) is preferably selected from the repeating units of formulae (IIa) to (IIm):

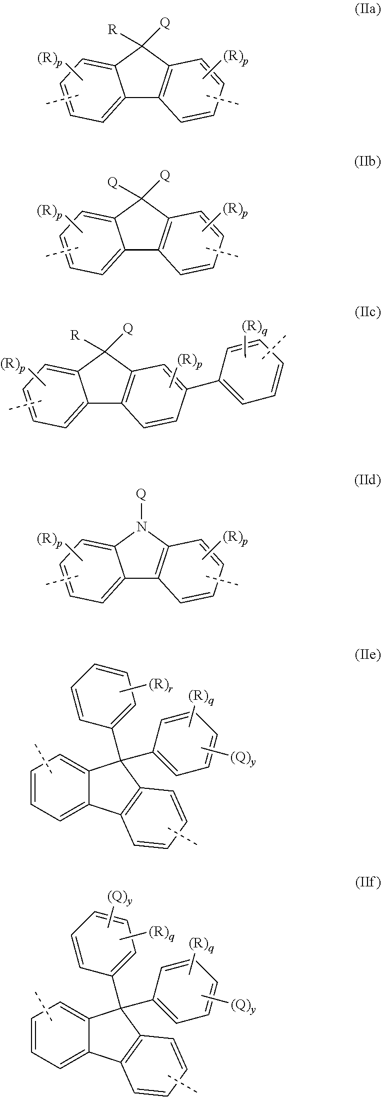

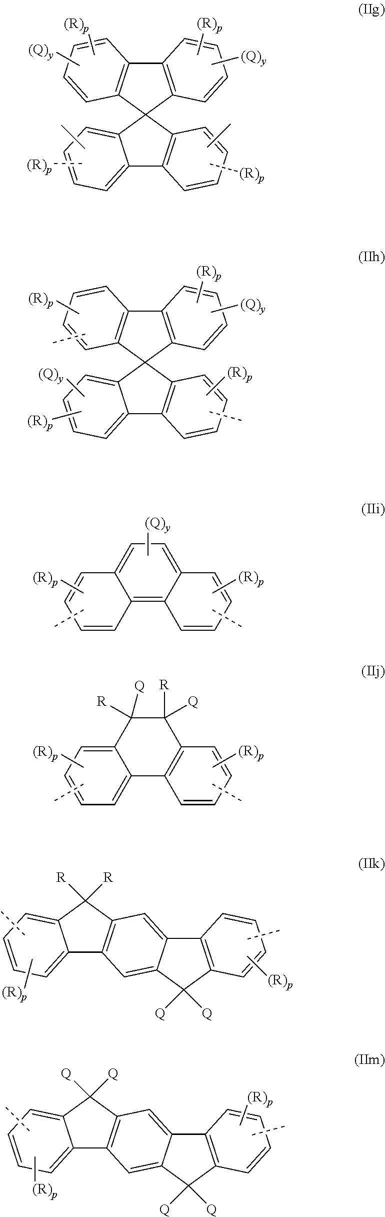

where

the radicals R in formulae (IIa) to (IIm) can adopt the same meaning as the radicals R in formula (I),

Q is a crosslinkable group,

p is 0, 1, 2 or 3,

q is 0, 1, 2, 3 or 4,

r is 0, 1, 2, 3, 4 or 5,

y is 1 or 2, and
the dashed lines represent bonds to adjacent repeating units in the polymer,
with the proviso, that with respect to one phenylene group the sum (p+y) is ≤4, and with the proviso, that in each repeating unit at least one y is ≥1, and
with the proviso, that with respect o tone phenylene group the sum (q+y) is ≤5, and with the proviso, that in each repeating unit at least one y is ≤1.

Crosslinkable groups Q which are preferred in accordance with the present invention are the groups mentioned below:

a) Terminal or Cyclic Alkenyl or Terminal Dienyl and Alkynyl Qroups:
Suitable units are those which contain a terminal or cyclic double bond, a terminal dienyl group or a terminal triple bond, in particular terminal or cyclic alkenyl, terminal dienyl or terminal alkynyl groups having 2 to 40 C atoms, preferably having 2 to 10 C atoms, where individual CH₂ groups and/or individual H atoms may also be replaced by the above-mentioned groups R. Furthermore suitable are also groups which are to be regarded as precursors and are capable of the in-situ formation of a double or triple bond.

b) Alkenyloxy, Dienyloxy or Alkynyloxy Qroups:
Furthermore suitable are alkenyloxy, dienyloxy or alkynyloxy groups, preferably alkenyloxy groups.

c) Acrylic Acid Qroups:
Furthermore suitable are acrylic acid units in the broadest sense, preferably acrylates, acrylamides, methacrylates and methacrylamides. C₁₋₁₀-alkyl acrylate and C₁₋₁₀-alkyl methacrylate are particularly preferred.

The crosslinking reaction of the groups mentioned above under a) to c) can take place via a free-radical, cationic or anionic mechanism, but also via cycloaddition.

It may be helpful to add a corresponding initiator for the crosslinking reaction. Suitable initiators for free-radical crosslinking are, for example, dibenzoyl peroxide, AIBN or TEMPO. Suitable initiators for cationic crosslinking are, for example, AlCl₃, BF₃, triphenylmethyl perchlorate or tropylium hexachloroantimonate. Suitable initiators for anionic crosslinking are bases, in particular butyllithium.

In a preferred embodiment of the present invention, however, the crosslinking is carried out without the addition of an initiator and is initiated exclusively thermally. This preference is due to the fact that the absence of the initiator prevents contamination of the layer, which could result in impairment of the device properties.

d) Oxetanes and Oxiranes:
A further suitable class of crosslinkable groups Q are oxetanes and oxiranes, which crosslink cationically by ring opening.

It may be helpful to add a corresponding initiator for the crosslinking reaction. Suitable initiators are, for example, AlCl₃, BF₃, triphenylmethyl perchlorate or tropylium hexachloroantimonate. Photoacids can likewise be added as initiators.

e) Silanes:
Furthermore suitable as a class of crosslinkable groups are silane groups SiR₃, where at least two groups R, preferably all three groups R, stand for Cl or an alkoxy group having 1 to 20 C atoms. This group reacts in the presence of water to give an oligo- or polysiloxane.

f) Cyclobutane Groups
The above-mentioned crosslinkable groups Q are generally known to the person skilled in the art, as are the suitable reaction conditions which are used for the reaction of these groups.

Preferred crosslinkable groups Q include alkenyl groups of the following formula Q1, dienyl groups of the following formula Q2, alkynyl groups of the following formula Q3, alkenyloxy groups of the following formula Q4, dienyloxy groups of the following formulae Q5, alkynyloxy groups of the following formula Q6, acrylic acid groups of the following formulae Q7 and Q8, oxetane groups of the following formulae Q9 and Q10, oxirane groups of the following formula Q11 and cyclobutane groups of the following formula Q12:

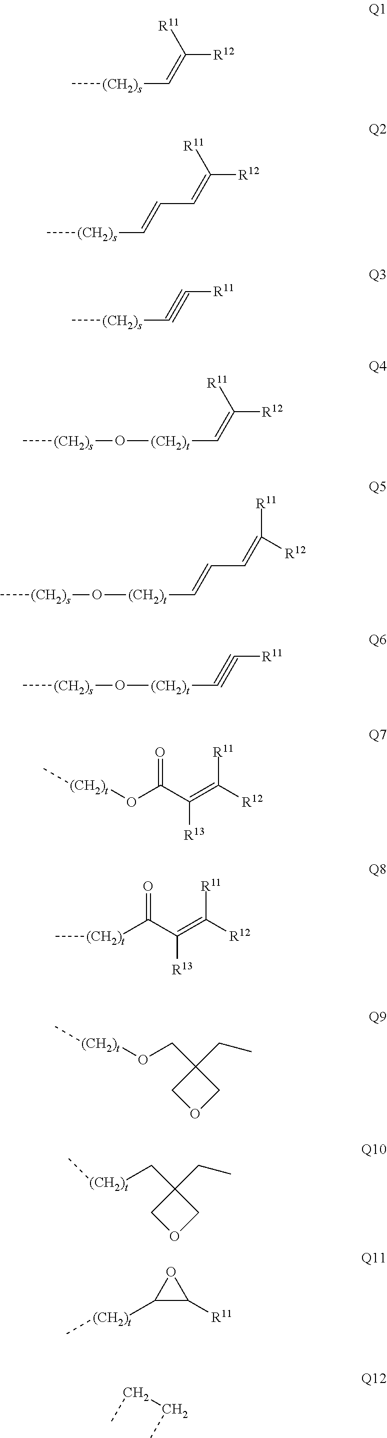

The radicals R¹¹, R¹² and R¹³ in the formulae Q1 to Q8 and Q11 are on each occurrence, identically or differently, H, a straight-chain or branched alkyl group having 1 to 6 C atoms, preferably 1 to 4 C atoms. The radicals R¹¹, R¹² and R¹³ are particularly preferably H, methyl, ethyl, n-propyl, isopropyl, n-butyl, sec-butyl or tert-butyl and very particularly preferably H or methyl. The indices used have the following meaning: s=0 to 8; and t=1 to 8.

The dashed bond in the formulae Q1 to Q11 and the dashed bonds in the formula Q12 represent the linking of the crosslinkable group to the structural units.

The crosslinkable groups of the formulae Q1 to Q12 may be linked directly to the structural unit, or else indirectly, via a further mono- or polycyclic, aromatic or heteroaromatic ring system Ar¹⁰, as depicted in the following formulae Q13 to Q24:

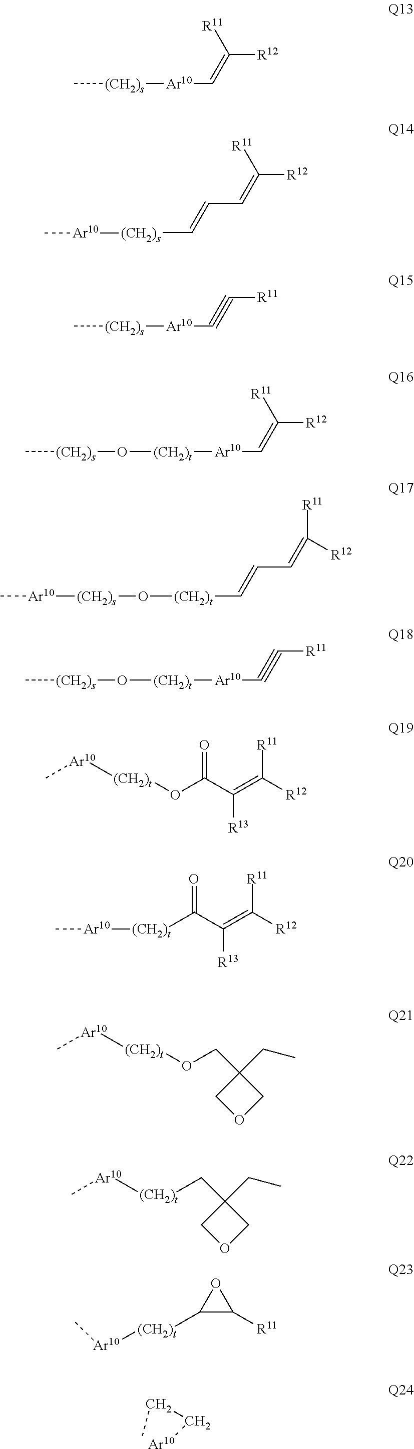

where Ar¹⁰ in the formulae Q13 to Q24 can adopt the same meanings as Ar¹.

More preferred crosslinkable groups Q are the following:

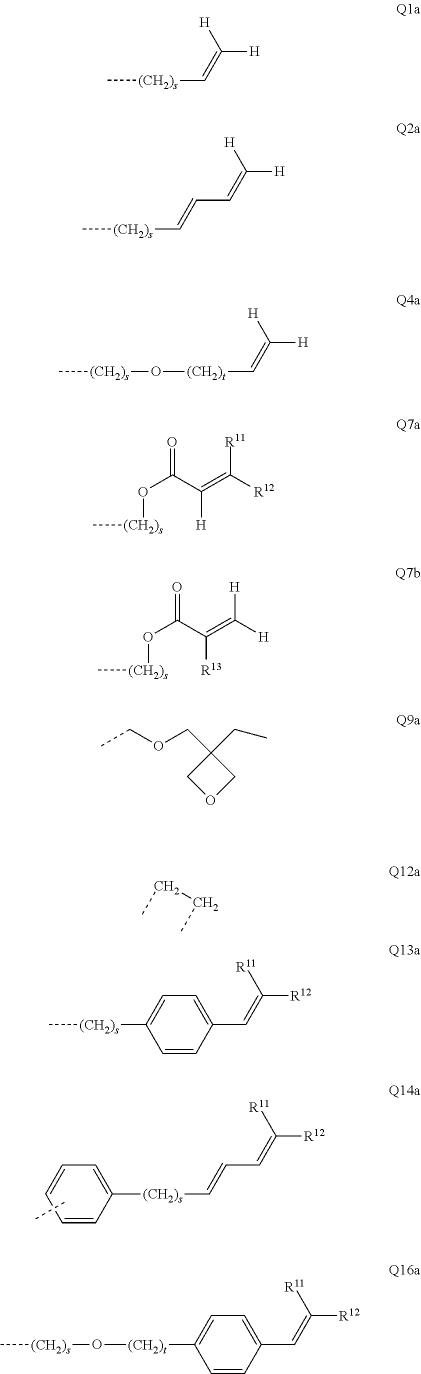

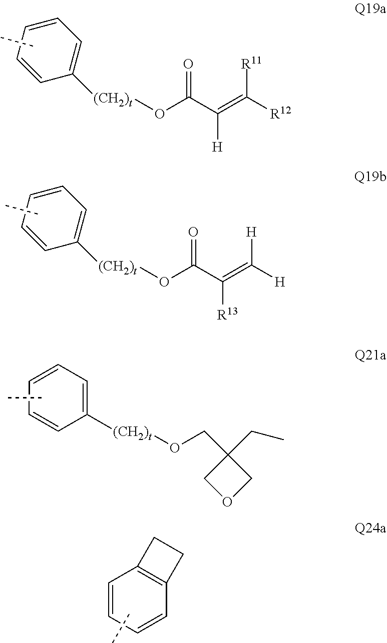

The radicals R¹¹ and R¹² in the formulae Q7a and Q13a to Q19a are on each occurrence, identically or differently, H or a straight-chain or branched alkyl group having 1 to 6 C atoms, preferably 1 to 4 C atoms. The radicals R¹¹ and R¹² are particularly preferably methyl, ethyl, n-propyl, isopropyl, n-butyl, sec-butyl or tert-butyl and very particularly preferably methyl.

The radical R¹³ in the formulae Q7b and Q19b is on each occurrence a straight-chain or branched alkyl group having 1 to 6 C atoms, preferably 1 to 4 C atoms. The radical R¹³ is particularly preferably methyl, ethyl, n-propyl, isopropyl, n-butyl, sec-butyl or tert-butyl and very particularly preferably methyl.

The indices used have the following meaning: s=0 to 8 and t=1 to 8.

Most preferred crosslinkable groups 0 are the following:

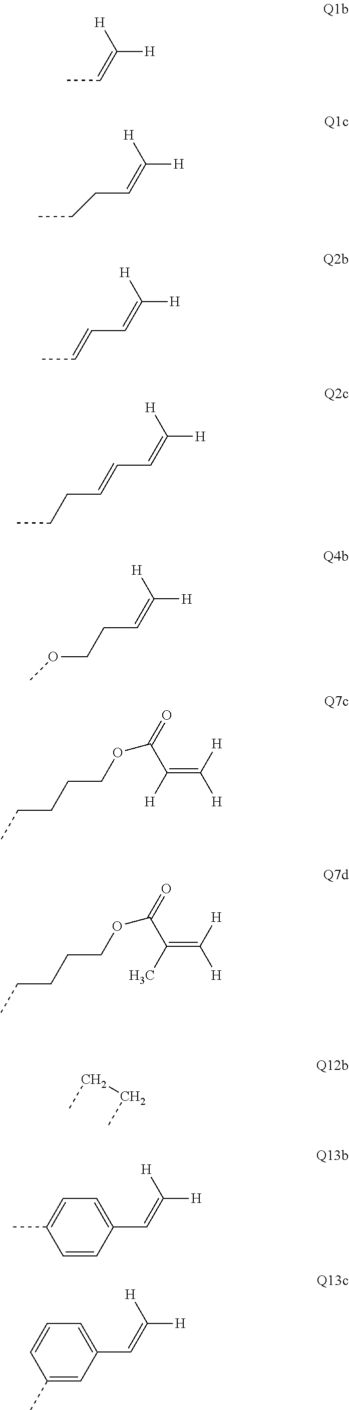

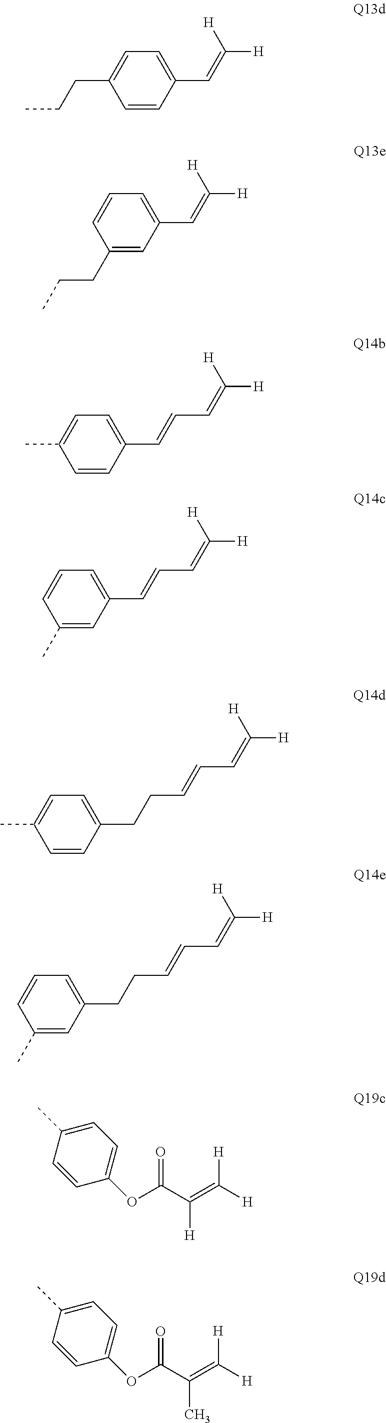

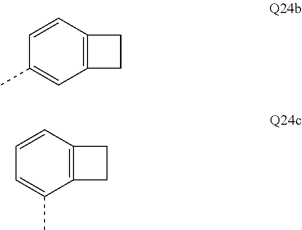

In the preferred groups Q1 to Q24, in the more preferred groups Q1a to Q24a and in the most preferred groups Q1b to Q24c, the dashed lines represent the bonds to the structural units. It should be noted in this connection that the groups Q12, Q12a, Q12b and Q24 each have two bonds to two adjacent ring carbon atoms of the repeating unit. All other crosslinkable groups have only one bond to the repeating unit.

The proportion of the crosslinkable repeating units of the formulae (I) or (II) in the polymer is in the range from 0.01 to 50 mol %, preferably in the range from 0.1 to 30 mol %, more preferably in the range from 0.5 to 25 mol % and most preferably in the range from 1 to 20 mol %, based on 100 mol % of all copolymerised monomers present as structural units in the polymer. This means, that the crosslinkable polymer according to the present invention, beside the crosslinkable repeating units of formulae (I) or (II), also contains further repeating units which are different from the crosslinkable repeating units of formulae (I) and (II).

These repeating units, which are different from the structural units of the formulae (I) and (II), are, inter alia, those as disclosed and extensively listed in WO 02/077060 A1 and in WO 2005/014689 A2. These are regarded as part of the present invention by way of reference. The further repeating units can originate, for example, from the following classes:
group 1: units which influence the hole-injection and/or hole-transport properties of the polymers;
group 2: units which influence the electron-injection and/or electron-transport properties of the polymers;
group 3: units which have combinations of individual units from group 1 and group 2;
group 4: units which modify the emission characteristics to such an extent that electrophosphorescence can be obtained instead of electrofluorescence;
group 5: units which improve transfer from the singlet state to the triplet state:
group 6: units which influence the emission colour of the resultant polymers;
group 7: units which are typically used as polymer backbone;
group 8: units which influence the film morphology and/or the rheological properties of the resultant polymers.

Preferred crosslinkable polymers according to the invention are those in which at least one repeating unit has charge-transport properties, i.e. which contain units from group 1 and/or 2.

The proportion of the at least one repeating unit which has charge-transport properties in the polymer is in the range from 10 to 80 mol %, preferably in the range from 15 to 75 mol %, more preferably in the range from 20 to 70 mol % and most preferably in the range from 40 to 60 mol %, based on 100 mol % of all repeating units in the polymer.

Repeating units from group 1 which have hole-injection and/or hole-transport properties are, for example, triarylamine, benzidine, tetraaryl-paraphenylenediamine, triarylphosphine, phenothiazine, phenoxazine, dihydrophenazine, thianthrene, dibenzo-para-dioxin, phenoxathiyne, carbazole, azulene, thiophene, pyrrole and furan derivatives and further O-, S- or N-containing heterocycles.

A preferred repeating unit having hole-injection and/or hole-transport properties is a triarylamine unit. The triarylamine unit is preferably a unit of the following formula (III):

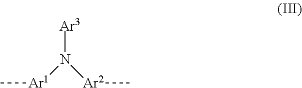

where
Ar¹ to Ar³ is on each occurrence, in each case identically or differently, a mono- or polycyclic, aromatic or heteroaromatic ring system having 5 to 60 aromatic ring atoms, which may be substituted by one or more radicals R;
R is on each occurrence, identically or differently, H, D, F, Cl, Br, I, N(R¹)₂, CN, NO₂, Si(R¹)₃, B(OR¹)₂, C(═O)R¹, P(═O)(R¹)₂, S(═O)R¹, S(═O)₂R¹, OSO₂R¹, a straight-chain alkyl, alkoxy or thioalkoxy group having 1 to 40 C atoms or a branched or cyclic alkyl, alkoxy or thioalkoxy group having 3 to 40 C atoms, each of which may be substituted by one or more radicals R¹, where one or more non-adjacent CH₂ groups may be replaced by R¹C═CR¹, C≡C, Si(R¹)₂, C═O, C═S, C═NR¹, P(═O)(R¹), SO, SO₂, NR¹, O, S or CONR¹ and where one or more H atoms may be replaced by D, F, Cl, Br, I or CN, or a mono- or polycyclic, aromatic or heteroaromatic ring system having 5 to 60 aromatic ring atoms, which may in each case be substituted by one or more radicals R¹, or an aryloxy or heteroaryloxy group having 5 to 60 aromatic ring atoms, which may be substituted by one or more radicals R¹, or an aralkyl or heteroaralkyl group having 5 to 60 aromatic ring atoms, which may be substituted by one or more radicals R¹, or a diarylamino group, diheteroarylamino group or arylheteroarylamino group having 10 to 40 aromatic ring atoms, which may be substituted by one or more radicals R¹, or a crosslinkable group Q, where two or more radicals R may also form a mono- or polycyclic, aliphatic, aromatic and/or benzo-fused ring system with one another;
R¹ is on each occurrence, identically or differently, H, D, F or an aliphatic hydrocarbon radical having 1 to 20 C atoms, an aromatic and/or a heteroaromatic hydrocarbon radical having 5 to 20 C atoms, in which, in addition, one or more H atoms may be replaced by F; where two or more substituents R¹ may also form a mono- or polycyclic, aliphatic or aromatic ring system with one another; and the dashed lines represent bonds to adjacent repeating units in the polymer.

The triarylamine unit is more preferably a unit of formula (III) wherein Ar³ is substituted by Ar⁴ in at least one, preferably in one of the two ortho positions, where Ar⁴ is a mono- or polycyclic, aromatic or heteroaromatic ring system having 5 to 60 aromatic ring atoms, which may be substituted by one or more radicals R.

Ar⁴ here may either be linked directly, i.e. via a single bond, to Ar³ or alternatively via a linking group X.

The structural unit of the formula (III) thus preferably has the structure of the following formula (IIIa):

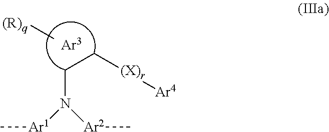

where Ar¹, Ar², Ar³, Ar⁴ and R can adopt the meanings indicated above,

q=0, 1, 2, 3, 4, 5 or 6, preferably 0, 1, 2, 3 or 4,

X=CR₂, NR, SiR₂, O, S, C═O or P═O, preferably CR₂, NR, O or S, and

r=0 or 1, preferably 0.

In a second embodiment, the at least one repeating unit of the formula (III) is characterised in that Ar³ is substituted by Ar⁴ in one of the two ortho positions, and Ar³ is additionally linked to Ar⁴ in the meta position that is adjacent to the substituted ortho position.

The repeating unit of the formula (III) thus preferably has the structure of the following formula (IIIb):

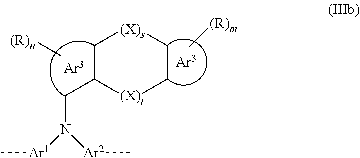

where Ar¹, Ar², Ar³, Ar⁴ and R can adopt the meanings indicated above,

m=0, 1, 2, 3 or 4,

n=0, 1, 2 or 3,

X=CR₂, NR, SiR₂, O, S, C═O or P═O, preferably CR₂, NR, O or S, and s and t are each 0 or 1, where the sum (s+t)=1 or 2, preferably 1.

In a preferred embodiment, the at least one repeating unit of the formula (III) is selected from the structural units of the following formulae (IV), (V) and (VI):

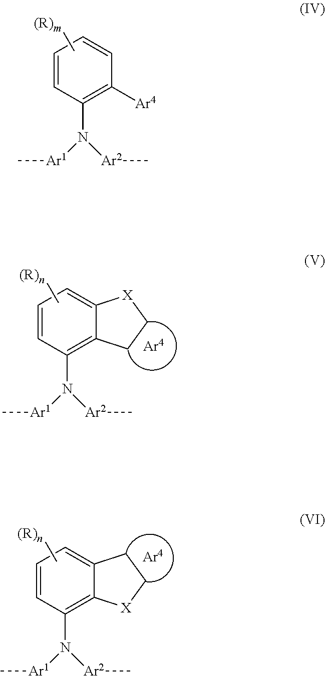

where Ar¹, Ar², Ar⁴ and R can adopt the meanings indicated above,

m=0, 1, 2, 3 or 4,

n=0, 1, 2 or 3, and

X=CR₂, NR, SiR₂, O, S, C═O or P═O, preferably CR₂, NR, O or S.

Further repeating units from group 1 are the structural units of the following formulae (1a) to (1q):

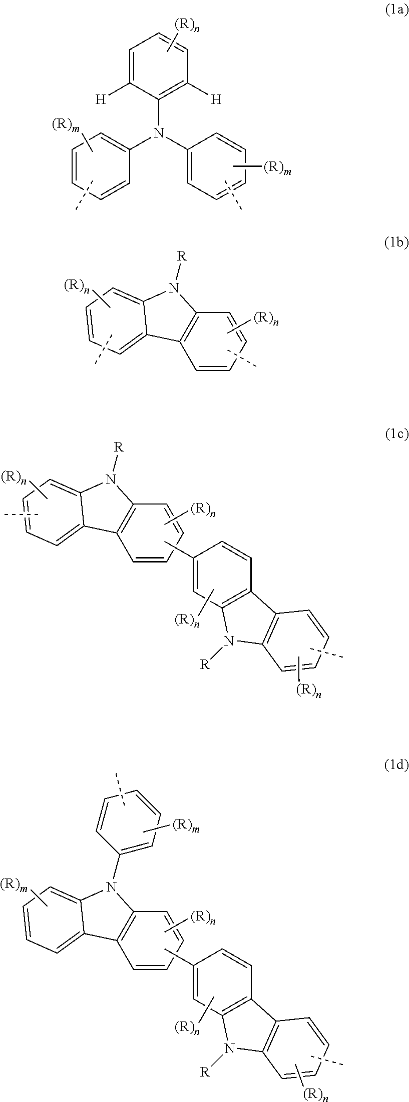

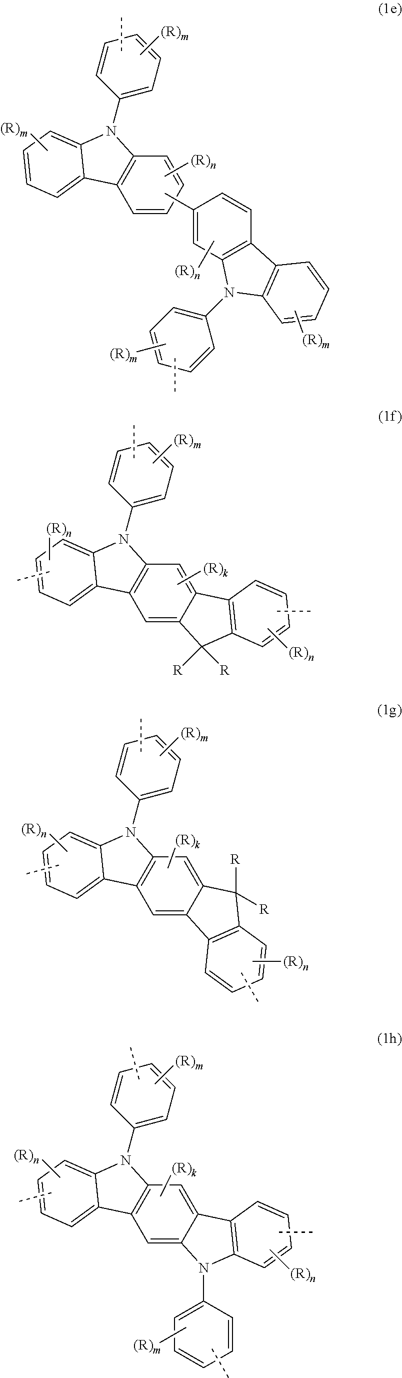

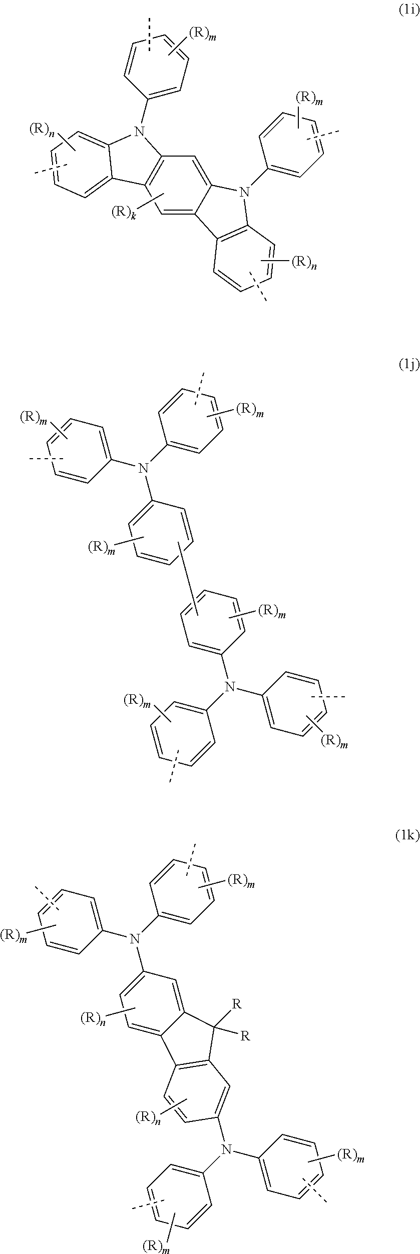

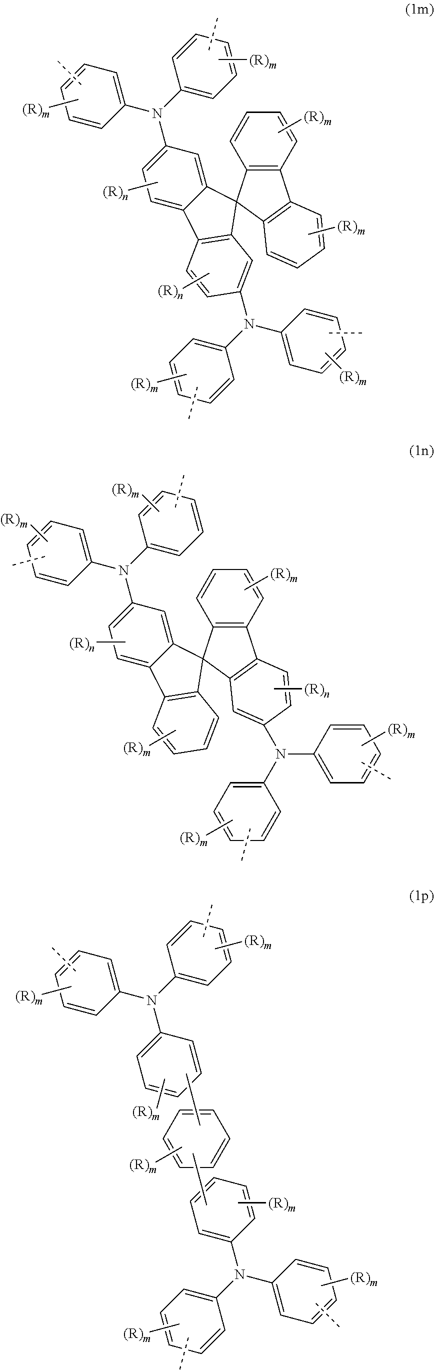

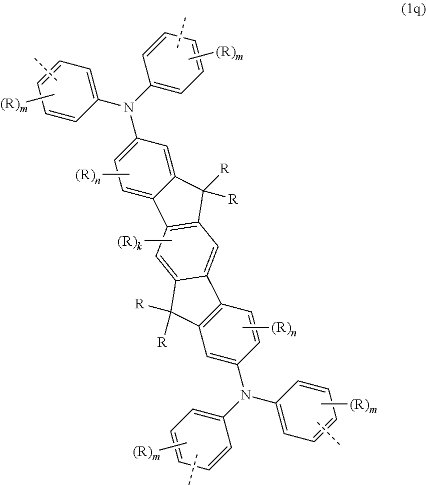

where R, k, m and n can adopt the meanings indicated above.

In the formulae (1a) to (1q), the dashed lines represent possible bonds to the adjacent repeating units in the polymer. If two dashed lines are present in the formulae, the repeating unit has one or two, preferably two, bonds to adjacent repeating units. If three dashed lines are present in the formulae, the repeating unit has one, two or three, preferably two, bonds to adjacent repeating units. If four dashed lines are present in the formulae, the repeating unit has one, two, three or four, preferably two, bonds to adjacent repeating units. They can be arranged here, independently of one another, identically or differently, in the ortho-, meta- or para-position.

Repeating units from group 2 which have electron-injection and/or electron-transport properties are, for example, pyridine, pyrimidine, pyridazine, pyrazine, oxadiazole, quinoline, quinoxaline, anthracene, benzanthracene, pyrene, perylene, benzimidazole, triazine, ketone, phosphine oxide and phenazine derivatives, but also triarylboranes and further O-, S- or N-containing heterocycles.

It may be preferred for the polymers according to the invention to contain units from group 3 in which structures which influence the hole mobility and structures which increase the electron mobility (i.e. units from group 1 and 2) are bonded directly to one another or to contain structures which increase both the hole mobility and the electron mobility. Some of these units can serve as emitters and shift the emission colour into the green, yellow or red. Their use is thus suitable, for example, for the generation of other emission colours from originally blue-emitting polymers.

Repeating units of group 4 are those which are able to emit light from the triplet state with high efficiency, even at room temperature, i.e. exhibit electrophosphorescence instead of electrofluorescence, which frequently causes an increase in the energy efficiency. Suitable for this purpose are firstly compounds which contain heavy atoms having an atomic number of greater than 36. Preference is given to compounds which contain d- or f-transition metals which satisfy the above-mentioned condition. Particular preference is given here to corresponding repeating units which contain elements of groups 8 to 10 (Ru, Os, Rh, Ir, Pd, Pt). Suitable repeating units for the polymers according to the invention here are, for example, various complexes, as described, for example, in WO 02/068435 A1, WO 02/081488 A1, EP 1239526 A2 and WO 2004/026886 A2. Corresponding monomers are described in WO 02/068435 A1 and in WO 2005/042548 A1.

Repeating units of group 5 are those which improve transfer from the singlet state to the triplet state and which, employed in support of the structural elements of group 4, improve the phosphorescence properties of these structural elements. Suitable for this purpose are, in particular, carbazole and bridged carbazole dimer units, as described, for example, in WO 2004/070772 A2 and WO 2004/113468 A1. Also suitable for this purpose are ketones, phosphine oxides, sulfoxides, sulfones, silane derivatives and similar compounds, as described, for example, in WO 2005/040302 A1.

Repeating units of group 6, besides those mentioned above, are those which have at least one further aromatic structure or another conjugated structure which do not fall under the above-mentioned groups, i.e. which have only little influence on the charge-carrier mobilities, are not organometallic complexes or do not influence singlet-triplet transfer. Structural elements of this type can influence the emission colour of the resultant polymers. Depending on the unit, they can therefore also be employed as emitters. Preference is given here to aromatic structures having 6 to 40 C atoms or also tolan, stilbene or bisstyrylarylene derivatives, each of which may be substituted by one or more radicals R. Particular preference is given here to the incorporation of 1,4- or 9,10-anthrylene, 1,6-, 2,7- or 4,9-pyrenylene, 3,9- or 3,10-perylenylene, 4,4′-tolanylene, 4,4′-stilbenylene, benzothiadiazole and corresponding oxygen derivatives, quinoxaline, phenothiazine, phenoxazine, dihydrophenazine, bis(thiophenyl)arylene, oligo(thiophenylene), phenazine, rubrene, pentacene or perylene derivatives, which are preferably substituted, or preferably conjugated push-pull systems (systems which are substituted by donor and acceptor substituents) or systems such as squarines or quinacridones, which are preferably substituted.

Preferred crosslinkable polymers according to the invention are those in which at least one repeating unit contains aromatic structures having 6 to 40 C atoms, which are typically used as polymer backbone.

The proportion of the at least one repeating unit which contains aromatic structures having 6 to 40 C atoms, which are typically used as polymer backbone, in the polymer is in the range from 10 to 80 mol %, preferably in the range from 15 to 75 mol %, more preferably in the range from 20 to 70 mol % and most preferably in the range from 40 to 60 mol %, based on 100 mol % of all repeating units in the polymer.

Repeating units of group 7 are units which contain aromatic structures having 6 to 40 C atoms, which are typically used as polymer backbone. These are, for example, 4,5-dihydropyrene derivatives, 4,5,9,10-tetrahydropyrene derivatives, fluorene derivatives, 9,9′-spirobifluorene derivatives, phenanthrene derivatives, 9,10-dihydrophenanthrene derivatives, 5,7-dihydro-dibenzoxepine derivatives and cis- and trans-indenofluorene derivatives, but also 1,2-, 1,3- or 1,4-phenylene, 1,2-, 1,3- or 1,4-naphthylene, 2,2′-, 3,3′- or 4,4′-biphenylylene, 2,2″-, 3,3″- or 4,4″-terphenylylene, 2,2′-, 3,3′- or 4,4′-bi1,1′-naphthylylene or 2,2′″-, 3,3′″- or 4,4′″-quaterphenylylene derivatives.

Preferred repeating units from group 7 are the structural units of the following formulae (7a) to (7q):

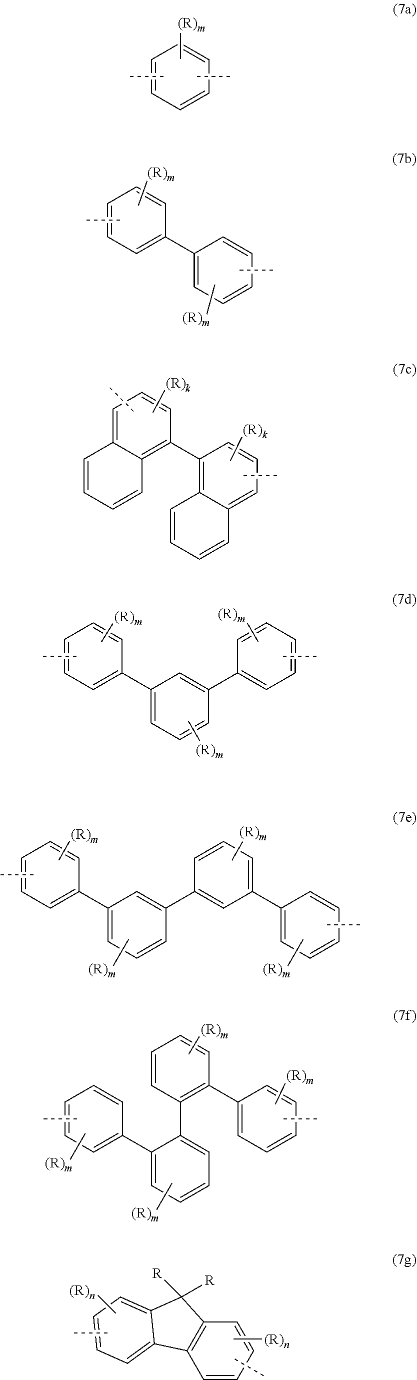

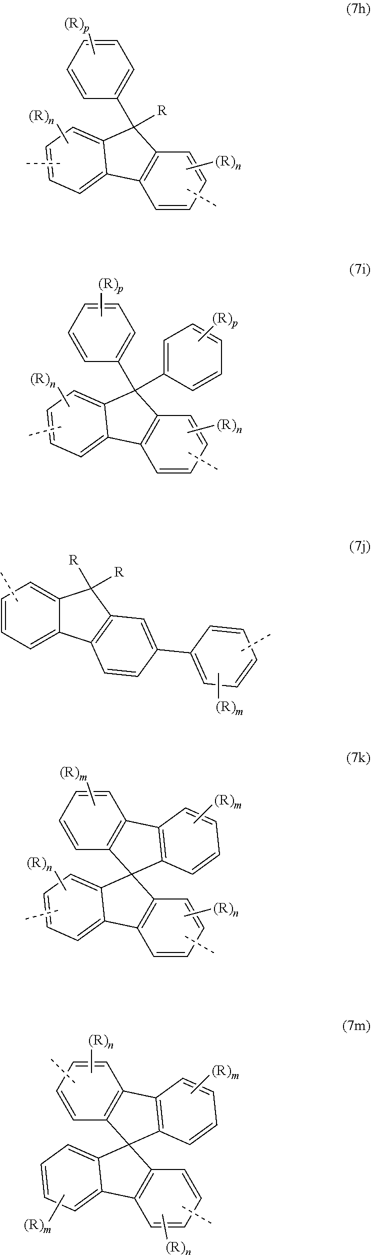

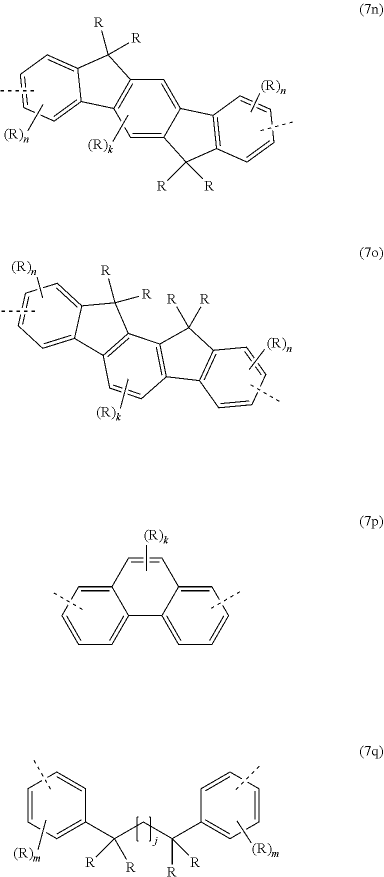

where R, k, m, n and p can adopt the meanings indicated above.

In the formulae (7a) to (7q), the dashed lines represent possible bonds to the adjacent repeating units in the polymer. If two dashed lines are present in the formulae, the repeating unit has one or two, preferably two, bonds to adjacent repeating units. They can be arranged here, independently of one another, identically or differently, in the ortho-, meta- or para-position.

Repeating units of group 8 are those which influence the film morphology and/or the rheological properties of the polymers, such as, for example, siloxanes, alkyl chains or fluorinated groups, but also particularly rigid or flexible units, liquid-crystal-forming units or crosslinkable groups.

Preference is given to crosslinkable polymers according to the present invention which simultaneously, besides repeating units of the formula (I) or (II), additionally also contain one or more units selected from groups 1 to 8. It may likewise be preferred for more than one further repeating unit from a group to be present simultaneously.

Preference is given here to polymers according to the present invention which, besides at least one structural unit of the formula (I) or (II), also contain units from group 7.

It is likewise preferred for the polymers according to the present invention to contain units which improve the charge transport or the charge injection, i.e. units from group 1 and/or 2.

It is furthermore more preferred for the polymers according to the present invention to contain repeating units from group 7 and units from group 1 and/or 2.

The polymers according to the present invention are either homopolymers or copolymers, preferably copolymers. The polymers according to the present invention may be linear or branched, preferably linear. Copolymers according to the invention may, besides one or more structural units of the formula (I) or (II), potentially have one or more further structures from the above-mentioned groups 1 to 8.

The copolymers according to the present invention can contain random, alternating or block-like structures or also have a plurality of these structures in an alternating manner. The copolymers according to the invention particularly preferably contain random or alternating structures. The copolymers are particularly preferably random or alternating copolymers. The way in which copolymers having block-like structures can be obtained and what further structural elements are particularly preferred for this purpose is described, for example, in detail in WO 2005/014688 A2. This is part of the present application by way of reference. It should likewise again be emphasised at this point that the polymer may also have dendritic structures.

The polymers according to the present invention containing repeating units of the formula (I) or (II) are generally prepared by polymerisation of one or more types of monomer, at least one monomer of which results in repeating units of the formula (I) or (II) in the polymer. Suitable polymerisation reactions are known to the person skilled in the art and are described in the literature. Particularly suitable and preferred polymerisation reactions which result in C—C or C—N links are the following:

(A) SUZUKI polymerisation;

(B) YAMAMOTO polymerisation;

(C) STILLE polymerisation;

(D) HECK polymerisation;

(E) NEGISHI polymerisation;

(F) SONOGASHIRA polymerisation;

(G) HIYAMA polymerisation; and

(H) HARTWIG-BUCHWALD polymerisation.

The way in which the polymerisation can be carried out by these methods and the way in which the polymers can then be separated off from the reaction medium and purified is known to the person skilled in the art and is described in detail in the literature, for example in WO 03/048225 A2, WO 2004/037887 A2 and WO 2004/037887 A2.

The C—C linking reactions are preferably selected from the groups of SUZUKI coupling, YAMAMOTO coupling and STILLE coupling.; the C—N linking reaction is preferably a HARTWIG-BUCHWALD coupling.

The present invention thus also relates to a process for the preparation of the crosslinkable polymers according to the invention, which is characterised in that they are prepared by SUZUKI polymerisation, YAMAMOTO polymerisation, STILLE polymerisation or HARTWIG-BUCHWALD polymerisation.

The polymers according to the invention can be used as pure substance, but also as mixture together with any desired further polymeric, oligomeric, dendritic or low-molecular-weight substances. Low-molecular-weight substance in the present invention is taken to mean compounds having a molecular weight in the range from 100 to 3000 g/mol, preferably 200 to 2000 g/mol. These further substances may, for example, improve the electronic properties or themselves emit. Mixture above and below denotes a mixture comprising at least one polymeric component. In this way, one or more polymer layers consisting of a mixture (blend) of one or more polymers according to the present invention containing a repeating unit of the formula (I) or (II) and optionally one or more further polymers can be prepared using one or more low-molecular-weight substances.

The present invention thus furthermore relates to a formulation containing a polymer blend comprising one or more polymers according to the invention, and one or more further polymeric, oligomeric, dendritic and/or low-molecular-weight substances.

As described above, the present invention relates to formulations comprising one or more polymers according to the present invention or a polymer blend in one or more solvents. The way in which such formulations can be prepared is known to the person skilled in the art and is described, for example, in WO 02/072714 A1, WO 03/019694 A2 and the literature cited therein.

These formulations can be used in order to produce thin polymer layers, for example by surface-coating methods (for example spin coating) or by printing processes (for example ink-jet printing).

Polymers containing repeating units which contain a crosslinkable group Q are particularly suitable for the production of films or coatings, in particular for the production of structured coatings, for example by thermal or light-induced in-situ polymerisation and in-situ crosslinking, such as, for example, in-situ UV photopolymerisation or photopatterning. It is possible here to use both corresponding polymers in pure substance, but it is also possible to use formulations or mixtures of these polymers as described above. These can be used with or without addition of solvents and/or binders. Suitable materials, processes and devices for the methods described above are described, for example, in WO 2005/083812 A2. Possible binders are, for example, polystyrene, polycarbonate, poly(meth)acrylates, polyacrylates, polyvinylbutyral and similar, opto-electronically neutral polymers.

The crosslinkable polymer of the formulation of the present invention is, after it has been applied, is crosslinked, which results in a crosslinked polymer. The crosslinkable group, which is particularly preferably a vinyl group or alkenyl group, is preferably incorporated into the polymer by the WITTIG reaction or a WITTIG-analogous reaction. If the crosslinkable group is a vinyl group or alkenyl group, the crosslinking can take place by free-radical or ionic polymerisation, which can be induced thermally or by radiation. Preference is given to free-radical polymerisation which is induced thermally, preferably at temperatures of less than 250° C., particularly preferably at temperatures of less than 230° C.

An additional styrene monomer is optionally added during the crosslinking process in order to achieve a higher degree of crosslinking. The proportion of the added styrene monomer is preferably in the range from 0.01 to 50 mol %, particularly preferably 0.1 to 30 mol %, based on 100 mol % of all copolymerised monomers which are present as structural units in the polymer.

The crosslinked polymers thus prepared are insoluble in all common solvents. In this way, it is possible to produce defined layer thicknesses which are not dissolved or partially dissolved again, even by the application of subsequent layers.

The crosslinked polymer is preferably produced in the form of a crosslinked polymer layer. Owing to the insolubility of the crosslinked polymer in all solvents, a further layer can be applied to the surface of a crosslinked polymer layer of this type from a solvent using the techniques described above.

It is also possible to produce so-called hybrid devices, in which one or more layers which are processed from solution and layers which are produced by vapour deposition of low-molecular-weight substances may occur.

The formulations according to the present invention can be used for the preparation of electronic or optoelectronic devices.

The present invention thus furthermore relates to the use of the formulations according to the invention for the preparation of electronic or optoelectronic devices, preferably organic electroluminescent devices (OLED), organic field-effect transistors (OFETs), organic integrated circuits (O-ICs), organic thin-film transistors (TFTs), organic solar cells (O-SCs), organic laser diodes (O-lasers), organic photovoltaic (OPV) elements or devices or organic photoreceptors (OPCs), particularly preferably organic electroluminescent devices (OLED).

In the case of the hybrid device mentioned above, the term combined PLED/SMOLED (polymeric light emitting diode/small molecule organic light emitting diode) systems is used in connection with organic electroluminescent devices.

The way in which OLEDs can be produced is known to the person skilled in the art and is described in detail, for example, as a general process in WO 2004/070772 A2, which should be adapted correspondingly for the individual case.

As described above, the polymers of the formulations according to the present invention are very particularly suitable as electroluminescent materials in OLEDs or displays produced in this way.

Electroluminescent materials in the sense of the present application are regarded as being materials which can be used as active layer. Active layer means that the layer is capable of emitting light on application of an electric field (light-emitting layer) and/or that it improves the injection and/or transport of positive and/or negative charges (charge-injection or charge-transport layer).

The polymers of the formulations according to the present invention are used in particular as electroluminescent material for the preparation of OLEDs.

The present invention furthermore relates to electronic or optoelectronic components, preferably organic electroluminescent devices (OLED), organic field-effect transistors (OFETs), organic integrated circuits (O-ICs), organic thin-film transistors (TFTs), organic solar cells (O-SCs), organic laser diodes (O-lasers), organic photovoltaic (OPV) elements or devices and organic photoreceptors (OPCs), particularly preferably organic electroluminescent devices, having one or more active layers, where at least one of these active layers is produced using a formulation according to the present application. The active layer can be, for example, a light-emitting layer, a charge-transport layer and/or a charge-injection layer.

The present application text and also the examples below are principally directed to the use of the formulations according to the invention in relation to OLEDs and corresponding displays. In spite of this restriction of the description, it is possible for the person skilled in the art, without further inventive step, also to use the formulations according to the invention for the further uses described above in other electronic devices.

The following examples are intended to explain the invention without restricting it. In particular, the features, properties and advantages described therein of the defined compounds on which the relevant example is based can also be applied to other compounds which are not described in detail, but fall within the scope of protection of the claims, unless stated otherwise elsewhere.

### WORKING EXAMPLES

Part A:

Synthesis of the Monomers

The monomers for preparing the crosslinkable polymer Po2 according to the present invention are already described in the prior art, are commercially available or are prepared according to the literature procedure and are summarized in the following Table 1:

TABLE 1

| monomer | structure | synthesis according to |
|---|---|---|
| Mo1-Bo | 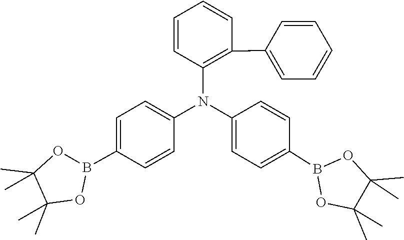 | WO 2013/156130 A1 |
| Mo2-Bo | 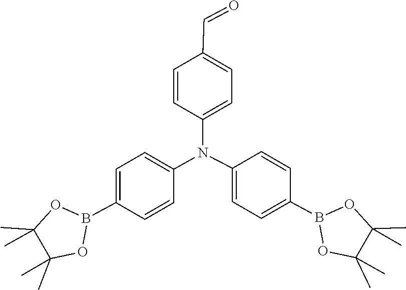 | WO 2010/097155 A1 |
| Mo3-Br | 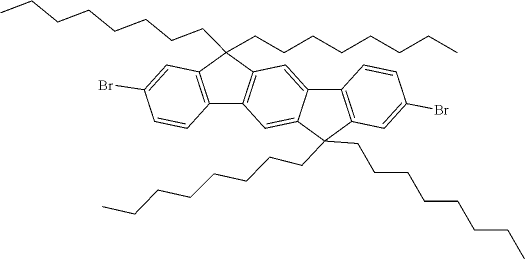 [SMILES: CCCCCCCCC1(CCCCCCCC)c2cc(Br)ccc2-c2cc3c(cc21)-c1ccc(Br)cc1C3(CCCCCCCC)CCCCCCCC] | Macromolecules 2000, 33, 2016-2020 |

Part B:

Synthesis of the Polymers

Preparation of polymer Po2 according to the present invention.

Polymer Po2 according to the present invention is prepared by SUZUKI coupling according to the method described in WO 2010/097155 A1 from the monomers disclosed in Part A.

Polymer Po2 prepared in this manner contains the structural units after removal of the leaving groups in the percentages indicated in Table 2 (percentages=mol %). In the case of polymer Po2 which is prepared from monomers which have aldehyde groups, these are converted into crosslinkable vinyl groups after the polymerization by means of the WITTIG reaction in accordance with the process described in WO 2010/097155 A1. The polymer listed in Table 2 and used in Part C thus has crosslinkable vinyl groups instead of the aldehyde groups originally.

The palladium and bromine contents of the polymer is determined by ICPMS. The determined values are below 10 ppm.

The molecular weight M_{w} and the polydispersity D are determined by means of gel permeation chromatography (GPC) (model: Agilent HPLC System Series 1100) (column: PL-RapidH from Polymer Laboratories, solvent: THF with 0.12% by volume o-dichlorobenzene, detection: UV and Refractive index, temperature: 40° C.). Calibration is with polystyrene standards.

TABLE 2

| Polymer | Mo A | % | Mo B | % | Mo C | % | Mw/D |
|---|---|---|---|---|---|---|---|
| Po2 | Mo3-Br | 50 | Mo1-Bo | 40 | Mo2-Bo | 10 | 82K |

Part C:

Preparation of the Polymer Inks

The polymer was mixed with each of the pure solvents mentioned in examples 1 to 5 of the following Table 3 in a glass bottle. The dissolution occurred at room temperature under magnetic stirring in argon atmosphere. After complete dissolution of the polymer, the ink was filtered through a 0.2 μm PTFE filter with argon overlay. If the ink was used for inkjet printing, the ink was additionally degassed at a reduced pressure of 20 mbar for 5 minutes.

| | | |
|---|---|---|
| Example 1 | 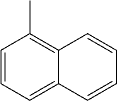 | 1-Methyl- naphthalene |
| Example 2 | 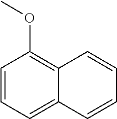 | 1-Methoxy- naphthalene |
| Example 3 | 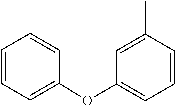 | 3-Phenoxy- toluene |
| Example 4 | 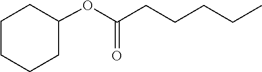 | Cyclohexyl- hexanoate |
| Example 5 | 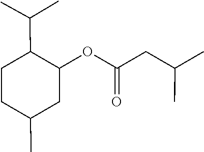 [SMILES: CC(C)CC(=O)OC1CC(C)CCC1C(C)C] | Menthyl- isovalerate |

Part D

Precipitation Test: Polymer-Solvent Affinity

Ethanol Precipitation Test

A 1.5 ml solution of polymer Po2 was prepared at 30 g/L with each solvent in glass bottles. A high concentration facilitated the visualization of the onset of the precipitation. Ethanol was added to the mixture dropwise under magnetic stirring. The amount of ethanol added at which the mixture started to precipitate (appeared milky) was recorded.

Acetone Precipitation Test

A 1.5 ml solution of polymer Po2 was prepared at 30 g/L with each solvent in glass bottles. Acetone was added to the mixture dropwise under magnetic stirring. The amount of acetone added at which the mixture started to precipitate (appeared milky) was recorded.

The volume of ethanol and acetone needed to start the precipitation of polymer Po2 (30 g/L) in different inks using different solvent is shown in the following table 4.

TABLE 4

| | Vol. % of | Vol. % of |
|---|---|---|
| Solvent | ethanol | acetone |
| 1-Methylnaphthalene | 30 | 178 |
| 1-Methoxynaphthalene | 27 | 180 |
| 3-Phenoxytoluene | 23 | 120 |
| Cyclohexylhexanoate | 21 | 97 |
| Menthylisovalerate | 13 | 59 |

Part E:

Preparation of the Thin Polymer Films

The solutions of examples 1 to 5 are filled into DMC cartridges. An Inkjet printer is used to deposit large area films of 20 mm×20 mm. After the films are deposited, they are dried under vacuum for 4 minutes under 10⁻³ mbar.

To proceed to the crosslinking reaction, the film is placed on a hotplate at 225° C. for 30 minutes under nitrogen atmosphere (glovebox).

Part F:

Characterization of the Stability of the Thin Polymer Films

The polymer inks were prepared at 5 g/L. A 4 cm² square layer was printed from each ink onto a glass substrate at a resolution adjusted from 362.86 DPI (Drop Per Inch) to 1270 DPI. The wet film was dried in a vacuum chamber at 10⁻⁴ mbar for 4 minutes. The dried layer was then annealed on a hotplate in a nitrogen atmosphere for 30 minutes at 225° C. to initiate the crosslinking reaction in the film.

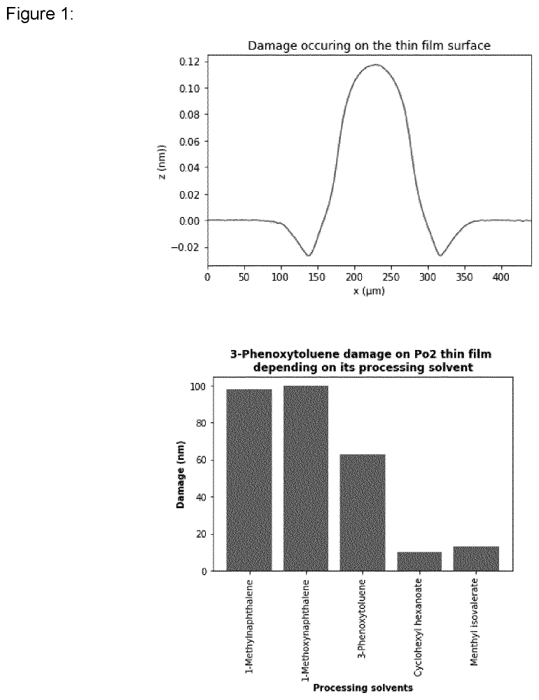

To test the solvent resistance of the thin polymer films having a thickness of 70 nm, 90 pl of 3-Phenoxytoluene (3-PT) was dropped by inkjet printing on the center of each layer. (A solvent in which the polymer has a high solubility is used to observe whether the crosslinking reaction successfully happened). After five minutes soaking, 3-Phenoxytoluene was dried in the vacuum chamber under 10⁻⁴ mbar for 4 minutes. The chemical damage was then characterized by surface analysis according to the method described in WO 2018/104202 A1. The damage was observed by interferometry and the cross-section of the damage was analysed. Thin films processed using a formulation of the present invention have a high solvent resistance, showed by a small damage observed on the film surface. The results are shown in the following table 5 as well as in FIG. 1.

TABLE 5

| Thin film | Damage (in nm) from 3-PT |
|---|---|
| processing solvent | on the thin film surface |
| 1-Methylnaphthalene | 98 |
| 1-Methoxynaphthalene | 100 |
| 3-Phenoxytoluene | 63 |
| Cyclohexylhexanoate | 10 |
| Menthylisovalerate | 13 |

As can be seen from table 5, the damage of the thin films of polymer Po2 decreases with a decreasing amount of ethanol as well as acetone needed to start the precipitation of the polymer in the respective formulation (see table 4).

This means that a thin polymer film processed from an ink formulation precipitating at 30 g/L if a lower amount of ethanol is added to the formulation is more stable against solvent exposure than a thin polymer film processed from an ink formulation precipitating at 30 g/L if a higher amount of ethanol is added to the formulation.

Consequently, thin polymer films processed from cyclohexylhexanoate and from Menthylisovalerate are more stable against solvent exposure than thin polymer films processed from 1-Methylnaphthalene, from 1-Methoxynaphthalene and from 3-Phenoxytoluene.

A high degree of crosslinking means that the damage is preferably less than 50 nm, more preferably less than 20 nm, based on an original thickness of 70 nm. This means that the damage is preferably less than 70%, more preferably less than 30%. Consequently, thin polymer films processed from cyclohexylhexanoate and from menthylisovalerate have a high degree of crosslinking.

Part G:

Quantification of the Degree of Crosslinking in the Thin Polymer Films

DSC (Differential Scanning Calorimetry) of the polymers was performed under ambient atmosphere using TA analysis Discovery DSC. Samples (ca. 2 mg) were measured in standard aluminum crucibles with a closed lid. Sample thermograms were recorded from a single heating ramp starting at room temperature to 300° C. at a heating rate of 20 K min⁻¹. The temperature range was determined by preliminary test runs so that the crosslinking reaction could occur. DSC measurements were done with the polymer powder and the polymer films. The powder was grinded with a pestle in a mortar for optimum thermal contact between the powder and the crucible. The polymer films were obtained by pouring 30 μl of a polymer solution of 50 g/L into the crucible. Most of the solvent was removed by placing the crucible into the vacuum chamber for two hours.

Degree of crosslinking X_{(Sx)}:

$${X}_{( Sx )} = \frac{Δ {H}_{( Sx )}}{Δ {H}_{( S 0 )}} * 100$$

ΔH_{(Sx)} enthalpy of polymer in film

ΔH_{(S0)} enthalpy of polymer in powder

The degree of crosslinking in a film processed from a formulation of the present invention is preferably >15%, more preferably >50%.

The DSC results from the films of polymer Po2 films obtained from the five IJP solvents of examples 1 to 5 are shown in the following Table 6.

TABLE 6

| | Crosslinking | Cross-linking |
|---|---|---|
| Solvent | enthalpy [J g⁻¹] | degree [%] |
| 1-Methylnaphthalene | 5.7 | 12.2 |
| 1-Methoxynaphthalene | 4.3 | 9.2 |
| 3-Phenoxytoluene | 6.4 | 15 |
| Cyclohexylhexanoate | 9.4 | 20.1 |
| Menthylisovalerate | 24.7 | 52.9 |
| Powder of Po2 | 46.7 | 100 |

Part H:

Kinetic Reaction of Crosslinking in Solution

The crosslinkable polymer Po2 was dissolved in the different solvents at a concentration of 50 g/L. Each of the polymer solution was divided into multiple glass bottles of 1 ml, so that each bottle could be heated at one specific temperature. After degassing and argon overlay, the bottles were sealed. The bottles were placed into an aluminum block covering the whole bottle (except the cap) standing on a hotplate. Each of these bottles was heated up at a fixed temperature for three hours while stirring to avoid a non-homogenous solution. After heating, the bottles were placed into a cold-water bath to cool down to room temperature. The viscosity of the solutions before and after the heating procedure was measured at room temperature, with a shear rate of 500 s⁻¹ by using Thermo Scientific™ HAAKE™ MARS™ III Rheometer. A very quick increase of viscosity regarding the heating temperature is characteristic of a fast kinetic reaction. The Formulations of the present invention lead to a fast crosslinking reaction.

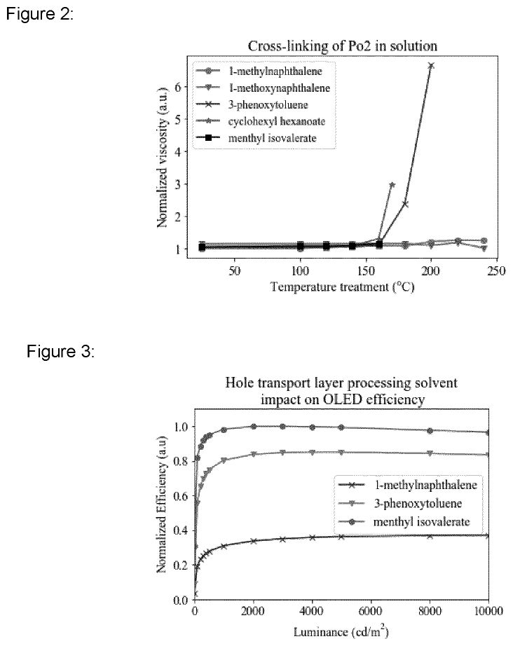

Consequently, ink formulations precipitating at 30 g/L if a lower amount of ethanol is added to the formulation have a faster crosslinking reaction than ink formulations precipitating at 30 g/L if a higher amount of ethanol is added to the formulation. The achieved results are shown in FIG. 2.

Part I:

Efficiency of OLED Device: Impact of the Hole Transport Layer Processing Solvent

Description of Fabrication Process

Glass substrates covered with pre-structured ITO and bank material were cleaned using ultrasonication in isopropanol followed by de-ionized water, then dried using an air-gun and a subsequent annealing on a hot-plate at 230° C. for 2 hours.

A hole-injection layer (HIL) using a composition of a polymer (e.g. polymer P2) and a salt (e.g. salt D1) as described in WO 2016/107668 A1 was inkjet-printed onto the substrate and dried in vacuum. The HIL was then annealed at 225° C. for 30 minutes in air.

On top of the HIL, a hole-transport layer (HTL) was inkjet-printed, dried in vacuum and annealed at 180° C. for 30 minutes in nitrogen atmosphere. As material for the hole-transport layer, polymer Po2, as described in the working examples of the present application in Part B, dissolved in different solvents at a concentration of 7 g/L was used.

The green emissive layer (G-EML) was also inkjet-printed, vacuum dried and annealed at 160° C. for 10 minutes in nitrogen atmosphere. The ink for the green emissive layer contained in all working examples two host materials (i.e. HM-1 and HM-2) as well as one triplett emitter (EM-1) prepared in 3-phenoxy toluene at a concentration of 12 g/L. The materials were used in the following ratio: HM-1:HM-2:EM-1=40:40:20. The structures of the materials are the following:

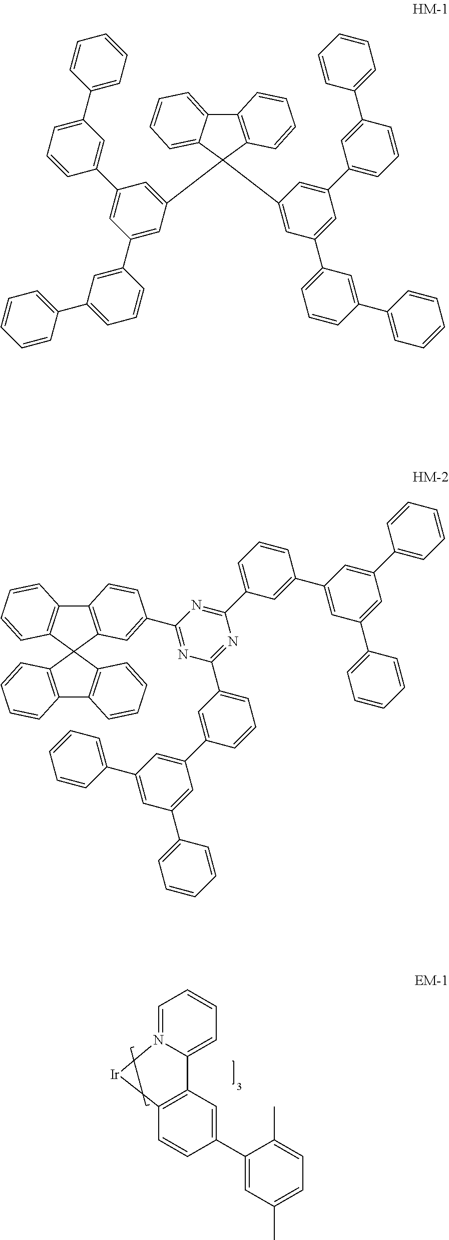

All inkjet printing processes were performed under yellow light and under ambient conditions.

The soluble layers were printed from a Dimatix cartridge by Pixdro LP50 printer. The printing process is composed of three steps for each layer: ink printing from the cartridge, solvent removal in a vacuum chamber, and heat treatment. The layers were dried for 3.5 minutes in a vacuum chamber under 10⁻⁴ mbar.

The devices were then transferred into a vacuum deposition chamber where the deposition of a common hole blocking layer (HBL), an electron-transport layer (ETL), and a cathode (Al) was done using thermal evaporation at a pressure of 10⁻⁷ mbar. The devices were then characterized in the glovebox.

In the hole blocking layer (HBL) ETM-1 was used as a hole-blocking material. The material has the following structure:

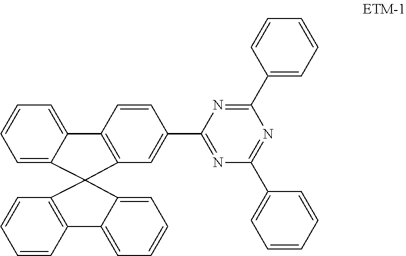 [SMILES: c1ccc(-c2nc(-c3ccccc3)nc(-c3ccc4c(c3)C3(c5ccccc5-c5ccccc53)c3ccccc3-4)n2)cc1]

In the electron transport layer (ETL) a 50:50 mixture of ETM-1 and LiQ was used. LiQ is lithium 8-hydroxyquinolinate.

Finally, the Al electrode is vapor-deposited. The devices were then encapsulated in a glove box in nitrogen using a cover glass and physical characterization was performed in ambient air.

An OLED is characterized by connecting the anode and cathode to a DC source and applying a voltage ramp. The incident photon currents are then measured with a calibrated photodiode at different voltages.

Simultaneously, the generated photocurrent was measured by a photodiode with the 6485 picoamperemeter from Keithley. The luminous efficiency of OLEDs can be defined as the ratio of luminance and current density:

$${η}_{L} = \frac{L}{j}$$

with the luminous efficiency η_{L} in cd/A, the luminance L in cd/m² and the current density j in mA/cm². The current density is calculated by

$$j = \frac{i}{A} ,$$

the current I and the active area A=4.606 mm².

### RESULTS AND DISCUSSION

Three OLED devices were printed where the influence of the hole transport processing solvent was studied. The HTL was processed either from 1-methylnaphthalene, from 3-phenoxytoluene or from menthyl isolalerate. As can be seen in FIG. 3, the OLED device obtained by processing the HTL with 1-methylnaphthalene shows a very small luminous efficiency, whereas the OLED device obtained by processing the HTL using menthyl isovalerate exhibits a high efficiency.

Consequently, ink formulations containing a solvent, precipitating at 30 g/L if a lower amount of ethanol is added to the formulation, show higher OLED device efficiencies when used to process the HTL than ink formulations containing a solvent, precipitating at 30 g/L if a higher amount of ethanol is added to the formulation.

1.-24. (canceled)

25. A formulation comprising at least one crosslinkable polymer and at least one organic solvent, wherein the at least one crosslinkable polymer is contained in the formulation in a concentration of at least 0.5 g/L, wherein the at least one organic solvent has a boiling point of at least 200° C., wherein the solubility of the at least one crosslinkable polymer in the at least one organic solvent is such that the crosslinkable polymer at a concentration of 30 g/L starts to precipitate if 60 vol.-% or less of ethanol is added to the formulation.

26. The formulation according to claim 25, wherein the formulation comprises one organic solvent.

27. The formulation according to claim 25, wherein the formulation comprises one crosslinkable polymer.

28. The formulation according to claim 25, wherein the crosslinkable polymer starts to precipitate if 45 vol.-% of less of ethanol is added to the formulation.

29. The formulation according to claim 25, wherein it has a viscosity of ≤25 mPas.

30. The formulation according to claim 25, wherein it has a surface tension in the range from 15 to 70 mN/m.

31. The formulation according to claim 25, wherein the at least one solvent is selected from 1-Methylnaphthalene, 1-Methoxynaphthalene, 3-Phenoxytoluene, Cyclohexylhexanoate and Menthylisovalerate.

32. The formulation according to claim 25, wherein the at least one crosslinkable polymer has a solubility of ≥0.5 g/L in the at least one organic solvent.

33. The formulation according to claim 25, wherein the concentration of the at least one crosslinkable in the formulation is in the range from 0.5 to 50 g/L.

34. The formulation according to claim 25, wherein the at least one crosslinkable polymer has a molecular weight M_{w} in the range from 1,000 to 2,000,000 g/mol.

35. The formulation according to claim 25, wherein the crosslinkable polymer contains at least one crosslinkable repeating unit.

36. The formulation according to claim 25, wherein the proportion of the at least one crosslinkable repeating unit in the crosslinkable polymer is in the range from 0.01 to 50 mol %, based on 100 mol % of all repeating units in the polymer.

37. The formulation according to claim 25, wherein the crosslinkable polymer contains at least one repeating unit which has charge transporting properties.

38. The formulation according to claim 25, wherein the proportion of the at least one repeating unit which has charge-transporting properties in the polymer is in the range from 10 to 80 mol %, based on 100 mol % of all repeating units in the polymer.

39. The formulation according to claim 25, wherein the crosslinkable polymer contains at least one repeating unit which contains aromatic structures having 6 to 40 C atoms, which are typically used as polymer backbone.

40. The formulation according to claim 25, wherein the proportion of the at least one repeating unit which contains aromatic structures having 6 to 40 C atoms, which are typically used as polymer backbone, in the polymer is in the range from 10 to 80 mol %, based on 100 mol % of all repeating units in the polymer.

41. A method comprising providing the a formulation according to claim 25 and preparing an electronic or optoelectronic device selected from the group consisting of organic electroluminescent devices (OLED), organic field-effect transistors (OFETs), organic integrated circuits (O-ICs), organic thin-film transistors (TFTs), organic solar cells (O-SCs), organic laser diodes (O-lasers), organic photovoltaic (OPV) elements or devices or organic photoreceptors (OPCs).

42. The method according to claim 41 for the preparation of organic electroluminescent devices (OLED).

43. An electronic or optoelectronic device selected from the group consisting of organic electroluminescent device (OLED), organic field-effect transistor (OFETs), organic integrated circuit (O-ICs), organic thin-film transistor (TFTs), organic solar cell (O-SCs), organic laser diode (O-lasers), organic photovoltaic (OPV) element or device and organic photoreceptor (OPCs), having one or more active layers, where at least one of these active layers comprises the formulation as claimed in claim 25.

44. A process for the preparation of an electronic or optoelectronic device having a layer containing a crosslinked polymer with a high degree of crosslinking, wherein
a) a formulation of the present invention is applied to a substrate or another layer via a deposition method,
b) the applied formulation is dried in that the at least one solvent is evaporated, and
c) the crosslinkable polymer is crosslinked.

45. The process according to claim 44, wherein as deposition method a printing technique is used.

46. The process according to claim 45, wherein as printing technique ink jet printing is used.

47. The process according to claim 44, wherein the crosslinking is conducted using elevated temperature.

48. A process for the preparation of an electronic or optoelectronic device, having a layer containing at least one crosslinked polymer with a specific degree of crosslinking, wherein this degree is obtained in that a formulation according to claim 25 is used,
wherein this degree can be increased in that at least one organic solvent having a boiling point of at least 200° C. is used in which the solubility of the at least one crosslinkable polymer is such that the at least one crosslinkable polymer at a concentration of 30 g/L starts to precipitate if a lower amount of ethanol is added to the formulation, and
wherein this degree can be decreased in that at least one organic solvent having a boiling point of at least 200° C. is used in which the solubility of the at least one crosslinkable polymer is such that the at least one crosslinkable polymer at a concentration of 30 g/L starts to precipitate if a higher amount of ethanol is added to the formulation.
